(19) United States
(12) Patent Application Publication
(10) Pub. No.: US 2019/0040314 A1
(43) Pub. Date: Feb. 7, 2019

(54) LUMINESCENT THIN FILM AND ORGANIC ELECTROLUMINESCENT ELEMENT

(71) Applicant: Konica Minolta, Inc., Tokyo (JP)

(72) Inventors: Hiroto ITO, Yokohama-shi, Kanagawa (JP); Hiroshi KITA, Hachioj-shi, Tokyo (JP)

(21) Appl. No.: 16/087,479

(22) PCT Filed: Mar. 30, 2017
(86) PCT No.: PCT/JP2017/013134

§ 371 Date: Sep. 21, 2018

(30) Foreign Application Priority Data
Mar. 31, 2016 (JP) 2016-070043

(51) Int. Cl. C09K 11/06; H05B 33/14; H01L 51/50; H01L 51/00

(52) U.S. Cl. CPC C09K 11/06; H05B 33/14; C09K 2211/1441; H01L 51/5004; H01L 51/0056; H01L 51/5016

(57) ABSTRACT

The objective of the present invention is to provide: a luminescent thin film which has high luminous efficiency and a long emission life; and an organic electroluminescent element which uses this luminescent thin film and has improved stability during continuous driving. A luminescent thin film according to the present invention is characterized by containing a phosphorescent metal complex and a host compound which forms an exciplex together with the phosphorescent metal complex.

### TECHNICAL FIELD

The present invention relates to a luminescent thin film and an organic electroluminescent element. More specifically, the present invention relates to a luminescent thin film having a high luminous efficiency and long luminescent lifetime, and an organic electroluminescent element having improved continuous driving stability (half-decay lifetime) by using the same luminescent thin film.

### BACKGROUND

Organic electroluminescence (it may be called as “organic EL”) is electric filed excited luminescence due to recombination of electrons and holes (sometimes they are collectively referred to as “carriers”). Since it produces a high luminous efficiency and it does not use harmful substance such as mercury at all, it is beginning to be used for electronic displays, lighting, illumination and electric decorations.

Further, in an organic electroluminescent element, different from a light emitting diode (LED), a portion that controls light emission is usually an amorphous thin film made of an organic compound. Therefore, light emission may be carried out not from a point, and it is possible to emit uniform large area up to maximum ten square centimeters. It is also possible to make it flexible by using a flexible substrate.

Further, in a production method of an organic electroluminescent element, there is no specific limitation as long as basically a thin film of several ten nanometers is produced. Besides heat evaporation methods, coating methods such as spin coating and die coating; printing methods such as flexographic printing, and screen printing; and on demand printing methods such as ink-jet printing and nozzle-jet printing may be applied. Moreover, when a shadow mask is employed in a heat evaporation method, pixels are relatively easily produced. Therefore, the organic electroluminescent element is now practically used for smartphones and television sets.

When the organic electroluminescent element is used as an industrial product, in particular, used for consumer electronic device, it is needless to say that its power consumption becomes important. As described above, the luminescent method of an organic EL generates light by recombination of electrons and holes. Therefore, its power consumption is low and environmental aptitude is high compared to conventional cathode-ray tube color televisions (CRD) and an incandescent lamps. However, since recent LEDs exhibit extremely high luminous efficiency, it is hard to say that organic EL elements still have a distinct advantage over liquid crystal displays and LED lighting using them as light sources.

Here, two kinds of light emission mechanisms in the organic EL element will be described.

When the luminescent material that is present in the light emitting layer of the organic EL element is a fluorescence emitting material, fluorescence is released from the singlet excited state of the luminescent material by electric field excitation to emit light. Conventionally, this luminescent material is called as “a light emitting dopant” or simply “a dopant” because a small amount thereof is used for doping. That is, the light emission mechanism is “a fluorescence emission”.

On the other hand, when the luminescent material is a phosphorescence emitting material, phosphorescence is released from the triplet excited state of the dopant by electric field excitation to emit light. The light emission mechanism is “a phosphorescence emission”.

Usually, an organic compound has a singlet ground state. When the organic compound is excited with light, since it does not involve spin reversal, it always becomes a singlet excited state. If heat is not emitted when the excited state returns to the ground state, that is, if all of the excitons are deactivated by radiation, it is possible to emit light with a quantum efficiency of 100%. When excitation is done by electricity (electric field), since the direction of an electron spin is random, the singlet excited state is generated with a probability of only 25%. The remaining 75% becomes in the triplet excited state.

In order to change from the triplet excited state to the singlet excited state, a forbidden transition accompanied by spin reversal is required. Usually, in this case, all is deactivated thermally (radiationless deactivation), and light emission is not obtained at all. That is, although it is obvious that phosphorescence emission is mechanistically preferable, in an organic EL element having a light emitting layer using a conventionally known “classical” fluorescent material, the phosphorescence phenomenon does not occur.

By considering this background, a phosphorescent organic EL element using a transition metal complex was found out by the group of Forest et al. at Princeton University (refer to Non-patent document 1, for example).

It was found out the following. In complexes of transition metals having large atomic weights such as platinum and iridium, the electron transition accompanying the spin inversion from the triplet, which is the forbidden transition, from the triplet to the singlet, and from the singlet to the triplet, is accelerated by the heavy atom effect. Further, by the selection of the ligand, a complex that can obtain phosphorescence with almost no radiationless deactivation was found. As a result, it is possible to realize an organic EL element achieving high luminous efficiency.

In fact, as of 2015, this phosphorescent light emission is applied to red light emission and green light emission for both smartphones and televisions.

However, the conventional fluorescent light emission is used for the blue light emission, and the organic EL element using the blue phosphorescence and the display using that organic EL element have not yet been realized.

The specificity of blue phosphorescent light emission, and its difficulty of practical application will be explained in detail later. At present, in general, when a light emitting layer of an organic EL element is formed using a phosphorescent compound, in order to suppress quenching due to concentration of a phosphorescent compound or quenching due to triplet-triplet annihilation, there are many cases in which a light emitting layer is formed by dispersing the phosphorescent compound (so-called “a dopant”) in an appropriate concentration in a matrix composed of a charge (carrier) conductive compound (so-called “a host compound”).

Therefore, it is known that in such a light emitting layer, the interaction between the dopant and the host compound and between the host compounds affects the efficiency and lifetime of phosphorescent light emission, and based on such knowledge research and development for improving luminous efficiency are progressing.

For example, a technique has been proposed in which an exciplex is formed with two types of host compound molecules, one is a host compound functioning as an electron donor and another is a host compound functioning as an electron acceptor, and energy is transferred to a dopant (refer to Patent document 1, for example). This technique can be said to be one means of reducing the decrease in luminous efficiency due to quenching in terms of reducing the probability of generating a triplet exciton of a host compound having a long exciton lifetime which is a factor of generating a quencher (quenching agent).

However, in this technique, since an exciplex is formed between two host compound molecules, it can be easily imagined that the contact probability between host molecules is greatly reduced in the vicinity of a dopant. Namely, since the probability that the host compound in the vicinity of the dopant affecting the light emitting property mostly becomes a triplet exciton increases, and it is considered that the host compound is not sufficiently effective, and it is thought that there is room for further improving luminous efficiency.

### PRIOR ART DOCUMENTS

### Patent Documents

Patent document 1: JP-A 2012-186461

### Non-Patent Document

Non-patent document 1: M. A. Baldo et al., Nature, vol. 395, 151-154 (1998)

### SUMMARY OF THE INVENTION

### Problems to be Solved by the Invention

The present invention has been made in view of the above-described problems and situation. An object of the present invention is to provide a luminescent thin film having a high luminescent efficiency and long luminescent lifetime, and to provide an organic electroluminescent element having improved continuous driving stability (half-decay lifetime) by using the same luminescent thin film.

### Means to Solve the Problems

That is, the above-described problem is resolved by the following constitutions.

1. A luminescent thin film comprising: a phosphorescent metal complex; and a host compound that forms an exciplex with the phosphorescent metal complex.
2. The luminescent thin film described in the item 1,

wherein the phosphorescent metal complex has a structure represented by Formula (1), and has a property of emitting light at room temperature.

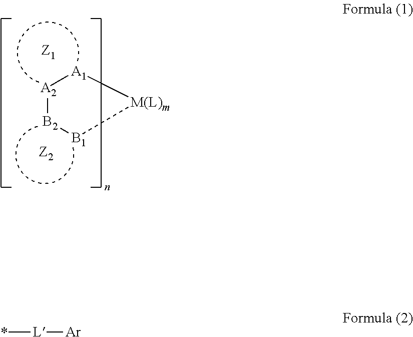

In the aforesaid Formula (1), M represents Ir or Pt; A₁, A₂, B₁, and B₂ each represent a carbon atom or a nitrogen atom; a ring Z₁ represents a 6-membered aromatic hydrocarbon ring, or a 5- or 6-membered aromatic heterocycle formed with A₁ and A₂. A ring Z₂ represents a 5- or 6-membered aromatic heterocycle formed with B₁ and B₂. One of a bond between A and M and a bond between B₁ and M is a coordination bond, and the other is a covalent bond. The ring Z₁ and the ring Z₂ each respectively may have a substituent, and at least one of the ring Z₁ and the ring Z₂ have a substituent having a structure represented by the aforesaid Formula (2). The substituent on the ring Z₁ and the substituent on the ring Z₂ may be bonded together to form a condensed ring structure. Ligands represented by the ring Z₁ and the ring Z₂ may be bonded together. L represents a monoanionic bidentate ligand coordinated to M, and L may have a substituent. m represents an integer of 0 to 2. n represents an integer of 1 to 4. When M represents Ir, (m+n) represents 3, and when M represents Pt, (m+n) represents 2. When m or n is an integer of 2 or more, the ligands represented by the ring Z₁ and the ring Z₂, and L each may be the same or different, and the ligand represented by the ring Z₁ and the ring Z₂ may be bonded to L.

In the aforesaid Formula (2), an asterisk (*) represents a linking site with the ring Z₁ or the ring Z₂ in the aforesaid Formula (1), and L′ represents a single bond or a linking group. Ar represents a substituent having an electron accepting property.

3. The luminescent thin film described in the item 1 or 2, comprising at least two kinds of host compounds,

wherein at least one kind of host compound is capable of forming an exciplex with the phosphorescent metal complex, and a plurality of the other kind of host compounds are capable of forming an exciplex with each other.

4. The luminescent thin film described in any one of the items 1 to 3,

wherein the host compound that forms the exciplex with the phosphorescent metal complex is a compound capable of emitting thermally activated delayed fluorescence.

5. The luminescent thin film described in any one of the items 1 to 4, satisfying the following Expression (I),

wherein LUMO(D) represents an energy level of a lowest unoccupied molecular orbital of the phosphorescent metal complex, HOMO(H) represents an energy level of a highest occupied molecular orbital of the host compound that forms the exciplex with the phosphorescent metal complex, and S₁ (min) represents a lower energy level obtained by comparing an energy level of an excited singlet state of the phosphorescent metal complex and an energy level of an excited singlet state of the host compound.

[LUMO(D)−HOMO(H)]−[S₁ (min)]<0 (eV) Expression (I):

6. An organic electroluminescent element comprising at least a light emitting layer between an anode and a cathode, wherein the light emitting layer contains the luminescent thin film described in any one of the items 1 to 5.

### Effects of the Invention

By the above-described means of the present invention, it is possible to provide a luminescent thin film having a high luminescent efficiency and long luminescent lifetime, and also to provide an organic electroluminescent element having improved continuous driving stability (half-decay lifetime) by using the same luminescent thin film.

An expression mechanism or an action mechanism of the effects of the present invention is not clearly identified, but it is supposed as follows.

When a phosphorescent metal complex (dopant) and a host compound according to the present invention are used, the host compound in the vicinity of the phosphorescent metal complex has a reduced probability of becoming a triplet exciton by forming an exciplex of the phosphorescent metal complex (dopant) with the host compound, even if these compounds take an unfavorable intermolecular interaction immediately after film formation and during driving.

As a result, the generation of quencher in the vicinity of the phosphorescent metal complex is reduced, and the lifetime of the phosphorescent organic electroluminescent element can be prolonged. The following two types of light emission mechanisms are conceivable.

That is, when an excited energy of an exciplex is lower than an excited energy of the phosphorescent metal complex (dopant) itself, an exciplex emission is observed in the longer wavelength side than the phosphorescence emission. And when an excited energy of an exciplex is equal to or larger than the excited energy of the dopant and the host compound, an energy transfer to the phosphorescent metal complex (dopant) and host compound will compete with the light emission of the exciplex itself, and the exciplex emission is taken place in the short wavelength region because the exciplex cannot transfer energy (refer to FIG. 8).

Further, by the intermolecular interaction between the acceptor of the phosphorescent metal complex (dopant) and host compound in the ground state, the dispersion stability of the dopant is improved and it is thought that deterioration of the light emitting property due to so-called concentration quenching is hardly to occur.

In our previous studies, we have considered that formation of exciplex of a phosphorescent metal complex and a host compound is an unnecessary or avoidable phenomenon in phosphorescence emission process.

This is because the exciplex formation phenomenon is generally considered by the person skilled in the art to increase luminous efficiency though making the energy levels of the excited singlet and the excited triplet to mutually similar levels for a fluorescent compound that thermally deactivates from the excited triplet state.

However, it is considered to be an unnecessary phenomenon for a phosphorescent metal complex capable of emitting phosphorescence from the excited triplet state. FIG. 1 illustrates an energy level diagram of a general phosphorescent metal complex (dopant) and host compound (hereafter, it may be called as “a host” in the figures). As illustrated here, since HOMO of the dopant is higher energy level than HOMO of the host compound, no exciplex is formed, and light emission is carried out by an exciton of the dopant itself. Conversely, as illustrated in FIG. 2, the phenomenon that the phosphorescent metal complex and the host compound forms an exciplex indicates the case that HOMO of the host compound is higher energy level than HOMO of the phosphorescent metal complex. The emitted light will have a longer wavelength, and it has been considered to be avoided for the blue phosphorescent metal complex that is required to emit light of short wavelength.

However, as a result of intensive studies, we have found that the durability of a luminescent thin film containing a host compound that forms an exciplex with a phosphorescent metal complex is very excellent, and that depending on the combination of the phosphorescent metal complex and the host compound, the exciplex emission wavelength does not necessarily become longer, and the present invention has been achieved.

As can be seen from the estimation of the above-described mechanism, although the present invention is effective to the green and red phosphorescent dopants, the present invention is more preferably applied to a blue phosphorescent dopant which is most susceptible to quencher influence.

### BRIEF DESCRIPTION OF THE DRAWINGS

FIG. 1 is an energy level diagram of a general dopant and a general host compound.

FIG. 2 is an energy level diagram of a dopant and a host compound according to the present invention.

FIG. 3 is a schematic diagram of an intermolecular interaction form between a dopant and a host compound.

FIG. 4 is a schematic perspective view illustrating an example of a display device using an organic EL element of the present invention.

FIG. 5 is a schematic perspective view illustrating an example of a constitution of a display section A illustrated in FIG. 4.

FIG. 6 is a schematic perspective view illustrating an example of a lighting device using an organic EL element of the present invention.

FIG. 7 is a schematic perspective view illustrating an example of a lighting device using an organic EL element of the present invention.

FIG. 8 is an example of an emission spectrum of a luminescent thin film.

FIG. 9 is a schematic diagram illustrating various kinds of embodiments of exciplex formation.

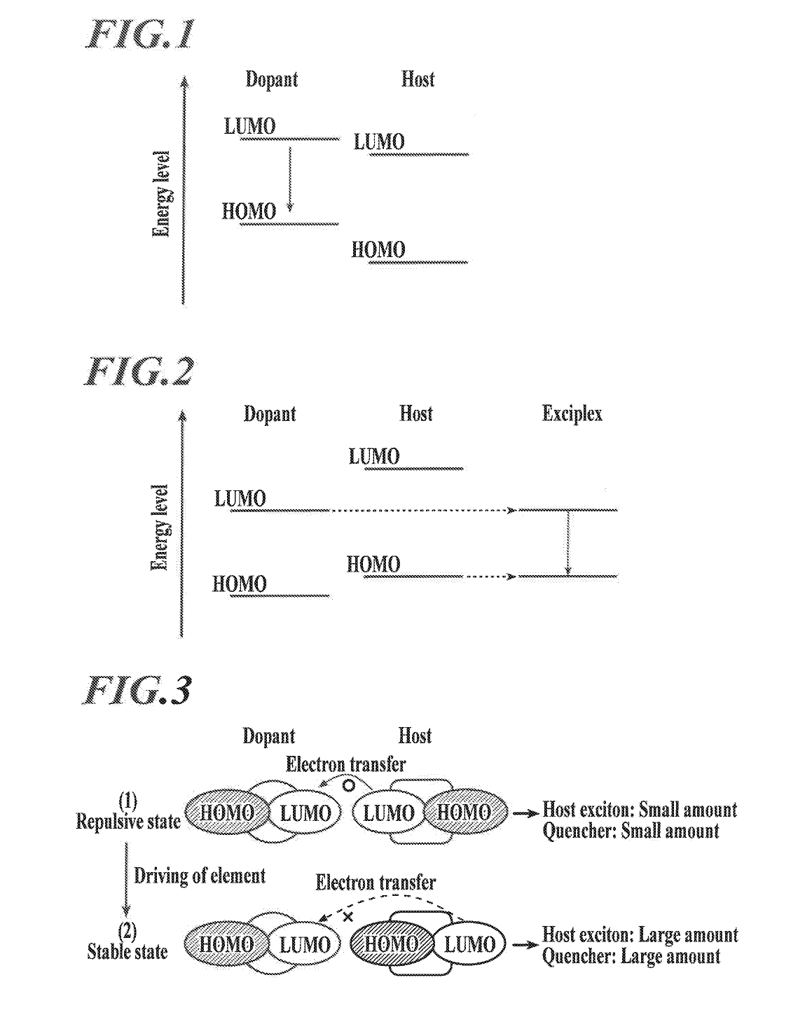

### EMBODIMENTS TO CARRY OUT THE INVENTION

A luminescent thin film of the present invention is characterized in containing a phosphorescent metal complex; and a host compound that forms an exciplex with the phosphorescent metal complex. This feature is a technical feature common to the invention according to each claim.

As an embodiment of the present invention, it is preferable that the phosphorescent metal complex has a structure represented by Formula (1), and has a property of emitting light at room temperature from the viewpoint of exhibiting the effect of the present invention.

In order to further increase the effect of the present invention, it is preferable that the luminescent thin film contains at least two kinds of host compounds, and at least one kind of host compound is capable of forming an exciplex with the phosphorescent metal complex, and a plurality of the other kind of host compounds are capable of forming an exciplex with each other.

Further, from the same viewpoint, it is preferable that the host compound that forms the exciplex with the phosphorescent metal complex is a compound capable of emitting thermally activated delayed fluorescence.

In one embodiment of the present invention, it is preferable that the above-described Expression (I) is satisfied. In Expression (I), LUMO(D) represents an energy level of a lowest unoccupied molecular orbital of the phosphorescent metal complex, HOMO(H) represents an energy level of a highest occupied molecular orbital of the host compound that forms the exciplex with the phosphorescent metal complex, and S₁ (min) represents a lower energy level obtained by comparing an energy level of an excited singlet state of the phosphorescent metal complex and an energy level of an excited singlet state of the host compound.

That is, when one of the phosphorescent metal complex and the host compound becomes an excited singlet state, and the aforesaid Expression (I) is satisfied, an exciplex is preferentially produced because an exciplex energy [LUMO(D)−HOMO(H)] formed via interaction with a ground state of other compound is more stable than the excited singlet state energy [S₁ (min)].

The luminescent thin film of the present invention is suitably used in a light emitting layer of an organic electroluminescent element.

In the present invention, the energy level of the lowest unoccupied molecular orbital (LUMO), the energy level of the highest occupied molecular orbital (HOMO), and the energy level of the excited singlet state (S₁) of each compound in Expression (I) may be determined by the following method.

They may be determined as a calculated value (as eV unit conversion value) with a molecular orbital calculation software Gaussian 98 (Gaussian 98, Revision A. 11.4, M. J. Frisch et al., Gaussian, Inc., Pittsburgh Pa., 2002), and by performing structure optimization with B3LYP/6-31G* as a key word. The reason why this calculated value is valid is that the correlation between the calculated value and the experimental value obtained by this method is high.

In the following, the fundamental items concerning the present invention are explained from the viewpoint of principle and mechanism before describing in detail the luminescent thin film and its constituting elements of the present invention. In the present description, when two figures are used to indicate a range of value before and after “to”, these figures themselves are included in the range as a lowest limit value and an upper limit value.

### 1. Specificity of Blue Phosphorescence

The reason why blue phosphorescence is difficult to achieve is examined in the following.

First, the magnitude of energy level difference between the excited state and the ground state of the molecule is one of the reasons.

Almost all of carbon, nitrogen, oxygen, sulfur and other metal element that form an organic compound constitute the molecule by covalent bonds. These covalent bonds have energy levels necessary for decomposition called a bond dissociation energy, and they are easily cleaved by ultraviolet rays and electric fields.

However, by using the stabilization method called π conjugation, it is possible to rigidify the molecule itself. By extending the a conjugation to form a large degenerate A conjugation, it is possible to considerably eliminate instability peculiar to organic compounds.

However, as this π conjugation is enhanced, the energy level difference between the excited state and the ground state becomes narrower, and the light emission becomes longer wavelength, that is, red shift occurs.

In addition, more disadvantageously, the triplet excited state (T₁) is always at a position where the energy level is lower than that of the singlet excited state. For that reason, the emission that glows blue in fluorescence becomes green or red light with a longer wavelength than blue in phosphorescence.

For example, anthracene, which emits fluorescence in a blue-violet color, emits phosphorescence at low temperature, but the emission color in that case becomes a red color.

Therefore, in order to make the green phosphorescent substance to be the red phosphorescent property, this can be achieved by bringing the molecule (complex) in a more stabilized direction. In order to make it blue, we have to bring the molecule in a direction to weaken the π conjugation, resulting in instability of the molecule itself.

Further, a host compound has a role to transfer energy or a carrier to a light emitting dopant. If the host compound does not completely prevent the reverse energy transfer from the dopant to the host compound, the luminous efficiency decreases. Therefore, it is necessary to widen the energy level difference between the excited state and the ground state, which is also one of the factors for reducing the emission lifetime.

The next factor having major influence is energy transfer to the quenching agent (quencher). It is known that emission of an organic EL element is hindered by a very small amount of water or impurities. The reason is that the quencher generated with passage of time due to their presence absorbs energy from the excited luminescent dopant.

As described above, the energy level of the triplet excited state of the blue phosphorescent dopant is lower than that of the green and red phosphorescence. Consequently, it is susceptible to the influence of the quencher generated in the element over time, and its reaction rate is about 100 to 10,000 times of the green phosphorescent dopant, which can be said to hamper the prolongation of the light emission lifetime.

Further, even when compared with a blue fluorescent dopant having the same luminescent color, the S₁ energy of the blue fluorescent dopant is equivalent to the T₁ energy of the blue phosphorescent dopant of the same luminescent color. As a result, the energy of the phosphorescent dopant is lower in the energy comparison of the triplet excited state, and the quenching rate by the quencher becomes faster for the same reason as above.

In addition, a phosphorescent dopant that undergoes forbidden transition has an exciton half-life (exciton lifetime) of about 100 to 1,000 times larger than that of a fluorescent dopant that returns to the ground state with allowable transition also causes a factor of increasing a extinction rate. The above-described factors synergistically adversely affect the lifetime. Therefore, the emission lifetime of the blue phosphorescent organic EL element is short, and it is the biggest factor impeding practical application in the organic EL display.

### 2. The Roles of Host Compound and Dopant and the Fundamental Problem Derived Therefrom.

In principle, it is sufficient for the light emitting layer of the organic EL element to be formed only with a light emitting substance. Almost all fluorescent substances and phosphorescent substances cause concentration quenching due to interaction between the molecules when present in high concentrations. Therefore, it is necessary to prepare the environment so as not to cause multi-molecular aggregation among the luminescent substances by diluting with an appropriate substance. For this reason, a substance called a host compound is usually made to coexist with a light emitting dopant to form a light emitting layer.

As a role of the host compound, in addition to the concentration quenching prevention, a function of transmitting electric field energy to the dopant, or a function of playing a role of transferring carriers of either electrons or holes to the dopant is required.

For the dopant to emit light, energy may be transferred from excitons of the host compound to emit light, or holes may be transferred from the host compound where the dopant is present as a radical anion and the dopant may serve as an exciton to emit light. Naturally, it may be a mechanism that delivers electrons from a host compound to a dopant that becomes a radical cation. It is necessary for the dopant to be in an efficient excited state eventually in order to improve the light emission efficiency of the organic EL element, and its mechanism may be whatever it is.

In the actual case of a red phosphorescent organic EL element, it is known that there are two coexisting mechanisms. One is a mechanism (energy transfer mechanism) that emits light by energy transfer from a host compound and the other is a mechanism that emits light by carrier transfer from a host compound (carrier trapping mechanism).

In the case of blue phosphorescence, an energy transfer mechanism and a carrier trapping mechanism both may be used depending on the molecular structure of a light emitting dopant and the molecular structure of a host compound. However, as described for the problem of the energy level difference between the excited state and the ground state, the host compound in the blue phosphorescent element requires more energy level difference between the excited state and the ground state than the blue phosphorescent dopant. Therefore, it is theoretically difficult to restrain the decomposition or the transformation in the excited state. It was found by our research that the lifetime of the light emitting element becomes longer by reducing effectively the probability of the host compound to be in the excited state.

On the other hand, it is basically impossible to completely preventing generation of the excited sate of the host compound in the light emitting layer of the blue phosphorescent element by an active action, that is, by a molecular design or a layer design. The excited state of the host compound is inevitably formed to some extent.

Especially when the host compound is in a triplet excited state with a long exciton existence time, it becomes fatal to the emission lifetime. As described above, the host compound becomes a triplet excited state in an amount of 75% by electric filed excitation, and further, in a host compound having no heavy atom in the molecule, it becomes a big problem that the existence time in the triplet exciton is several orders of magnitude longer than that of the dopant.

### 3. How to Prolong Emission Lifetime of Blue Phosphorescence

### 3.1 Rigidifying Light Emitting Substance (Dopant) Itself

The first step in prolonging the emission lifetime of the blue phosphorescent element is to stabilize the dopant itself, which is a light emitting substance.

Generally, the fact that an ortho-metallated complex of platinum or iridium is used as a phosphorescent dopant is because this complex is thermally and chemically very stable. However, the lifetime thereof is still too short to apply to an electronic display.

### 3.2 Suppression of Heat Generation by Improving Luminous Efficiency

In addition to such fundamental improvement, improving technologies peculiar to an organic EL element have also been developed.

When an organic EL element is represented by an equivalent electric circuit of electricity, it is represented by a resistor and a diode. This means that when an electric current is passed in the element, Joule heat is always produced inside of the element.

The organic EL element is characterized by being a laminate of an amorphous film formed by an organic compound. On the other hand, the luminescent thin film has a glass transition temperature (Tg), and the molecules start to move when the temperature exceeds to the glass transition temperature even locally. As a result, crystallization or phase transfer is taken place, which causes an undesirable phenomenon to emission lifetime of the organic EL element.

The origin of this Joule heat is caused by the nonradiative deactivation of the molecule in an extreme argument. Higher luminous efficiency should result in less heat generation. However, both luminous efficiency and luminous lifetime change drastically depending on the type of the material used, layer thickness, and layer composition. Therefore, there are few reports of quantitative research example.

Although it is lacking in objectivity, according to our many years study in a blue phosphorescent organic EL element, it has been demonstrated that in a blue phosphorescent element with enhanced luminous efficiency of the organic EL element close to the theoretical limit, the element with higher luminous efficiency has longer emission lifetime. This suggests that the two major performance of the organic EL element does not become a tradeoff. It is an important element as one of the aspects towards prolonging the life.

### 3.3 to Know the Fundamental Problem of Short Lifetime of Blue Phosphorescent Element

Here, the fundamental factors in the emission lifetime of the blue phosphorescent element are summarized.

(1) Increasing the energy level difference between the excited state and the ground state of the luminescent dopant and the host compound directly leads to the fragility of the molecule.
(2) When the energy level of the triplet excited state of the luminescent dopant is low and triplet exciton lifetime is long, due to the synergistic effect of these two, the extinction speed by the quencher becomes extremely fast.
(3) To generate an exciton of a host compound having a larger energy level difference between the excited state and the ground state than the light emitting dopant In particular, to produce the triplet exciton, and to produce quenchers such as decomposition products, reaction products, and aggregates.

In short, how to solve these problems is indispensable for making a blue phosphorescent organic electroluminescent element into practical use. As a result of intensive studies for over many years to solve these problems, we concluded that intermolecular interaction between the phosphorescent dopant and the host compound is important. The present invention is an entirely new technical concept that is unequivocal to solve the fundamental problem and provides realistic technical means.

### 4. About Intermolecular Interaction Between Phosphorescent Dopant and Host Compound

### 4.1 Intermolecular Interaction State Between Dopant and Host Compound

As described in the item 2, in order to improve the luminous efficiency, it is a necessary condition to transfer electrons from the host compound in the radical anion state to the dopant in the radical cation state to result in making the phosphorescent dopant to be in the excited state.

Further, as described in the item 3.3, it is necessary to suppress the triplet exciton formation of the host compound and not to generate a quencher. That is, in order to prolong the lifetime of the phosphorescent element, it can be said that these two necessary conditions are maintained immediately after film formation and after driving the element over time.

This necessary condition at the molecular level is examined.

There are the following two interaction states of the host compound located in proximity to the LUMO orbital which is the electron receiving site of the phosphorescent dopant (refer to FIG. 3).

(1) The LUMO orbital of the host compound exists near the LUMO orbit of the dopant.
(2) The HOMO orbital of the host compound exists near the LUMO orbit of the dopant.

In the above-described case (1), it can be said that it is a good condition in which electron transfer rapidly occurs from the host compound in the radical anion state to the dopant, thereby a dopant exciton is easily formed, and a triplet exciton of the host compound is hardly formed.

On the other hand, in the above-described case (2), electron transfer from the host compound in the radical anion state to the dopant hardly occur, during which holes are trapped on the host compound, and carrier recombination occurs, thereby an exciton of the host compound is formed. In this case, the singlet exciton (25%) of the host compound rapidly transfers energy to the adjacent dopant and there is no energy loss, but because of the length of the exciton lifetime of the triplet exciton (75%), there is a competition process between Dexter energy transfer to the dopant and nonradiative deactivation. It is accompanied by an unfavorable state change of generation of quenchers such as decomposition products, reaction products, and aggregates due to energy loss or thermal host molecular motion.

### 4.2 Change in Intermolecular Interaction During Electric Field Driving of Phosphorescent Element

Next, this molecular state will be further examined from the viewpoint of fluctuation before and after element driving.

Immediately after the film formation, the dopant and the host compound are in an amorphous state (random orientation), and there is a high possibility that the above-described cases (1) and (2) occur with approximately the same frequency.

However, due to device driving, the molecule repeats molecular motion such as change to the radical state and the excited state from the ground state several hundred million times, and during that process the intermolecular molecules in the organic layer change more thermally and electrically stable state. The electrically stable state means that the state changes from the electrically repulsive state (1) to the electrically stable state (2) in the same way as the magnet behavior. In other words, it may be imagined that, the intermolecular interaction form of the host compound and the dopant changes to the above-described (2) (refer to FIG. 3) during device driving, which is not desirable as a luminescent property.

As described above, when the dopant and the host compound are in an electrically stable state, the probability that the host compound becomes a triplet exciton increases, and as a result, deterioration such as aggregation and decomposition is likely to occur. Alteration of this host compound becomes a quencher which deprives the light emission energy of the dopant and accompanies decrease in light emitting property. Naturally, the closer the distance between the dopant and the quencher is, the more easily the quencher deprives the dopant of the excitation energy, and the light emitting property is lowered. That is, it can be said that suppressing alteration of the host compound in the vicinity of the dopant is very important for maintaining the light emitting property, that is, for prolonging the lifetime of the element.

In the following, the luminescent thin film of the present invention and its constituting elements will be described in detail.

### <<Luminescent Thin Film>>

The luminescent thin film of the present invention is characterized by containing a phosphorescent metal complex and a host compound that forms an exciplex with the phosphorescent metal complex.

Formation of an exciplex can be found by comparing the emission spectra of the phosphorescent metal complex and the host compound. When an exciplex is formed, it has a peak in a region different from the single emission spectrum of the phosphorescent metal complex and the host compound.

As an embodiment of the present invention, from the viewpoint of exhibiting the effect of the present invention, it is preferable that the phosphorescent metal complex has a structure represented by the following Formula (1) and has a property of emitting light at room temperature.

The content of the phosphorescent metal complex or the host compound in the luminescent thin film of the present invention may be arbitrarily determined based on the conditions required for the product to be applied. It may be contained with a uniform concentration in the layer thickness direction of the light emitting layer or may have an arbitrary concentration distribution.

However, the content of the phosphorescent metal complex according to the present invention is preferably from 1 to 50 mass %, more preferably from 1 to 30 mass %, when the mass of the luminescent thin film is 100 mass % in order to suitably exhibit the luminescence phenomenon. In addition, the content of the host compound according to the present invention is preferably from 50 to 99 mass %, more preferably from 70 to 99 mass %, when the mass of the luminescent thin film is 100 mass %.

Next, “a phosphorescent metal complex” and “a host compound” contained in the luminescent thin film according to the present invention will be described in detail.

### <<Phosphorescent Metal Complex>>

In the present invention, a preferable phosphorescent metal complex is a metal complex having a structure represented by Formula (1) described below.

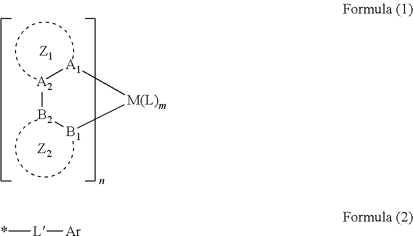

In the aforesaid Formula (1), M represents Ir or Pt; A₁, A₂, B₁, and B₂ each represent a carbon atom or a nitrogen atom; a ring Z₁ represents a 6-membered aromatic hydrocarbon ring, or a 5- or 6-membered aromatic heterocycle formed with A₁ and A₂. A ring Z₂ represents a 5- or 6-membered aromatic heterocycle formed with B₁ and B₂. One of a bond between A and M and a bond between B₁ and M is a coordination bond, and the other is a covalent bond. The ring Z₁ and the ring Z₂ each respectively may have a substituent, and at least one of the ring Z₁ and the ring Z₂ have a substituent having a structure represented by Formula (2). The substituent on ring Z₁ and the substituent on the ring Z₂ may be bonded together to form a condensed ring structure. Ligands represented by the ring Z₁ and the ring Z₂ may be bonded together. L represents a monoanionic bidentate ligand coordinated to M, and L may have a substituent. m represents an integer of 0 to 2. n represents an integer of 1 to 4. When M represents Ir, (m+n) represents 3, and when M represents Pt, (m+n) represents 2. When m or n is an integer of 2 or more, the ligands represented by the ring Z₁ and the ring Z₂, and L each may be the same or different, and the ligand represented by the ring Z₁ and the ring Z₂ may be bonded to L.

In the aforesaid Formula (2), an asterisk (*) represents a linking site with the ring Z₁ or the ring Z₂ in the aforesaid Formula (1). L′ represents a single bond or a linking group. Ar represents a substituent having an electron accepting property.

When a ring Z₁ represents a 6-membered aromatic hydrocarbon ring, examples of a 6-membered aromatic hydrocarbon ring are a naphthalene ring and an anthracene ring, which are a compound in which a benzene ring is further condensed with a 6-membered aromatic hydrocarbon ring.

When a ring Z₁ represents a 5- or 6-membered aromatic heterocycle, examples of a 5-membered aromatic heterocycle are: a pyrrole ring, a pyrazole ring, an imidazole ring, a triazole ring, a tetrazole ring, an oxazole ring, an isoxazole ring, a thiazole ring, an isothiazole ring, an oxadiazole ring, and a thiadiazole ring.

Among these, preferable rings are a pyrazole ring and an imidazole ring. A more preferable ring is an imidazole ring. These rings may be further substituted with a substituent selected form the following group of substituents. Preferable substituents are an alkyl group and an aryl group, and a more preferable substituent is a substituted or a non-substituted aryl group.

Examples of a 6-membered aromatic heterocycle include: a pyridine ring, a pyrimidine ring, a pyridazine ring, and a pyrazine ring.

A ring Z₂ preferably represents a 5-membered aromatic heterocycle. As a 5-membered aromatic heterocycle, the 5-membered aromatic heterocycles indicated for ring Z₁ may be cited. In particular, at least one of B₁ and B₂ is preferably a nitrogen atom.

Examples of a substituent (except for a substituent represented by Formula (2)) include: an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, and a pentadecyl group); a cycloalkyl group (for example, a cyclopentyl group, and a cyclohexyl group); an alkenyl group (for example, a vinyl group, an allyl group); an alkynyl group (for example, an ethynyl group and a propargyl group); an aromatic hydrocarbon group (also called an aromatic hydrocarbon ring, an aromatic carbon ring group or an aryl group, for example, a phenyl group, a p-chlorophenyl group, a mesityl group, a tolyl group, a xylyl group, a naphthyl group, an anthryl group, an azulenyl group, an acenaphthenyl group, a fluorenyl group, a phenantolyl group, an indenyl group, a pyrenyl group, and a biphenyl group); an aromatic heterocyclic group (for example, a pyridyl group, a pyrazyl group, a pyrimidinyl group, a triazyl a group, a furyl group, a pyrrolyl group, an imidazolyl group, a benzimidazolyl group, a pyrazolyl group, a pyrazinyl group, a triazolyl group (for example, 1,2,4-triazol-1-yl group, and 1,2,3-triazol-1-yl group), an oxazolyl group, a benzoxazolyl group, a thiazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, an azacarbazolyl group (indicating a ring structure in which one of the carbon atoms constituting the carbazole ring of the carbazolyl group is replaced with nitrogen atoms), a quinoxalinyl group, a pyridazinyl group, a triazinyl group, a quinazolinyl group, and a phthalazinyl group); a heterocyclic group (for example, a pyrrolidyl group, an imidazolidyl group, a morpholyl group, and an oxazolidyl group); an alkoxy group (for example, a methoxy group, an ethoxy group, a propyloxy group, a pentyloxy group, an hexyloxy group, an octyloxy group, and a dodecyloxy group); a cycloalkoxy group (for example, a cyclopentyloxy group and a cyclohexyloxy group); an aryloxy group (for example, a phenoxy group and a naphthyloxy group); an alkylthio group (for example, a methylthio group, an ethylthio group, a propylthio group, a pentylthio group, hexylthio group, an octylthio group, and a dodecylthio group); a cycloalkylthio group (for example, a cyclopentylthio group and a cyclohexylthio group); an arylthio group (for example, a phenylthio group and a naphthylthio group); an alkoxycarbonyl group (for example, a methyloxycarbonyl group, an ethyloxycarbonyl group, a butyloxycarbonyl group, an octyloxycarbonyl group, and a dodecyloxycarbonyl group); an aryloxycarbonyl group (for example, a phenyloxycarbonyl group and a naphthyloxycarbonyl group); a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group); an acyl group (for example, an acetyl group, an ethyl carbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group); an acyloxy group (for example, an acetyloxy group, an ethylcarbonyloxy group, a butylcarbonyloxy group, an octylcarbonyloxy group, a dodecylcarbonyloxy group, and a phenylcarbonyloxy group); an amido group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethyhexylcarbonylamino group, an octylcarbonylamino group, a dodecylcarbonylamino group, a phenylcarbonylamino group, and a naphthylcarbonylamino group); a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethymexylaminocarbonyl group, a dodecylaminocarbonyl group, a phenylaminocarbonyl group, a naphthylaminocarbonyl group, and a 2-pyridylaminocarbonyl group); a ureido group (for example, a methylureido group, an ethylureido group, a pentylureido group, a cyclohexylureido group, an octylureido group, a dodecylureido group, a phenylureido group, a naphthylureido group, and a 2-pyridylaminoureido group); a sulfinyl group (for example, a methylsulfinyl group, an ethylsufinyl group, a butylsulfinyl group, a cyclohexylsulfinyl group, a 2-ethylhexylsulfinyl group, a dodecylsulfinyl group, a phenylsulfinyl group, a naphthylsulfinyl group, and a 2-pyridylsulfinyl group); an alkylsulfonyl group (for example, a methylsulfonyl group, an ethylsulfonyl group, a butylsulfinyl group, a cyclohexylsulfonyl group, a 2-ethylhexylsulfonyl group, and a dodecylsulfonyl group); an arylsulfonyl group or a heteroarylsulfonyl group (for example, a phenylsulfonyl group, a naphthylsulfonyl group, and a 2-pyridylsulfonyl group); an amino group (for example, an amino group, an ethylamino group, a dimethylamino group, a butylamino group, a cyclopentylamino group, a dodecylamino group, an anilino group, a naphthylamino group, and a 2-pyridylamino group); a halogen atom (for example, a fluorine atom, a chlorine atom and a bromine atom); a fluorinated hydrocarbon group (for example, a fluoromethyl group, trifluoromethyl group, a pentafluoroethyl group and a pentafluorophenyl group); a cyano group; a nitro group; a hydroxyl group; a mercapto group; a silyl group (for example, a trimethylsilyl group, a triisopropylsilyl group, a triphenylsilyl group, and a phenyldiethylsilyl group) and a phosphono group.

Moreover, these substituents may be further substituted by the aforesaid substituent. Further, a plurality of these substituents may be bonded with each other to form a ring.

Examples of a linking group represented by L′ in Formula (2) are: a substituted or non-substituted alkylene group having 1 to 12 carbon atoms, a substituted or non-substituted arylene group having 6 to 30 carbon atoms, a substituted or non-substituted heteroarylene group having 5 to 30 ring forming atoms, and a divalent linking group formed with combination of these groups.

An alkylene group having 1 to 12 carbon atoms may be a straight chain or a branched chain, or it may be a ring structure such as a cycloalkylene group. An arylene group having 6 to 30 carbon atoms may be a non-condensed or condensed ring.

Examples of an arylene group having 6 to 30 ring forming carbon atoms are: an o-phenylene group, an m-phenylene group, a p-phenylene group, a naphthalenediyl group, a phenanthrenediyl group, a biphenylene group, a terphenylene group, a quaterphcnylene group, a triphenylenediyl group, and a fluorencdiyl group.

Examples of a heteroarylene group having 5 to 30 ring forming atoms are derived from: a pyridine ring, a pyrazine ring, a pyrimidine ring, a piperidine ring, a triazine ring, a pyrrole ring, an imidazole ring, a pyrazole ring, a triazole ring, an indole ring, an isoindole ring, a benzimidazole ring, a furan ring, a benzofuran ring, an isobenzofuran ring, a dibenzofuran ring, a thiophene ring, a benzothiophene ring, a dibenzothiophcne ring, a silole ring, a benzosilole ring, a dibenzosilole ring, a quinoline ring, an isoquinoline ring, a quinoxaline ring, a phenanthridine ring, a phenanthroline ring, an acridine ring, a phenazine ring, a phenoxazine ring, a phenothiazine ring, a phenoxathin ring, a pyridine ring, a pyrazine ring, a pyrimidine ring, a pyridazine ring, a triazine ring, an acridine ring, an oxazole ring, an oxadiazole ring, a benzoxazole ring, a thiazole ring, a thiadiazole ring, a benzothiazole ring, a benzodifuran ring, a thienothiophene ring, a benzodithiophene ring, a cyclazine ring, a quindoline ring, a tepenidine ring, a quinindoline ring, a triphenodithiadine ring, a triphenodioxazine ring, a phenanthradine ring, an anthrazine ring, a perimidine ring, a naphthofuran ring, a naphthothiophene ring, a benzodithiophene ring, a naphthodifuran ring, a naphthodithiophene ring, an anthrafuran ring, an anthradifuran ring, an anthrathiophene ring, an anthradithiophene ring, a thianthrene ring, a phenoxathiin ring, a naphthothiophene ring, a carbazole ring, a carboline ring, a diazacarbazole ring (it indicates a ring structure in which arbitral two or more carbon atoms constituting the carbazole ring is replaced with nitrogen atoms), an azadibenzofuran ring (it indicates a ring structure in which arbitral one or more carbon atoms constituting the dibenzofuran ring is replaced with nitrogen atoms), azadibenzothiophene ring (it indicates a ring structure in which arbitral one or more carbon atoms constituting the dibenzothiohene ring is replaced with nitrogen atoms), an indolocarbazole ring, and an indenoindole ring.

A divalent group is derived from the aforesaid ring by removing two hydrogen atoms from the ring.

More preferable heteroarylene groups are a divalent group derived from the following by removing two hydrogen atoms in the ring: a pyridine ring, a pyrazine ring, a pyrimidine ring, a piperidine ring, a triazine ring, a dibenzofuran ring, a dibenzothiophene ring, a carbazole ring, a carboline ring, and a diazacarbazole ring.

Moreover, these substituents may be further substituted by the aforesaid substituent.

Examples of a substituent Ar having an electron accepting property in Formula (2) are: an aromatic heterocyclic group (for example, a pyridyl group, a pyrazyl group, a pyrimidinyl group, a triazyl a group, a furyl group, a pyrrolyl group, an imidazolyl group, a benzimidazolyl group, a pyrazolyl group, a pyrazinyl group, a triazolyl group (for example, 1,2,4-triazol-1-yl group, and 1,2,3-triazol-1-yl group), an oxazolyl group, a benzoxazolyl group, a thiazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, an azacarbazolyl group (indicating a ring structure in which one of the carbon atoms constituting the carbazole ring of the carbazolyl group is replaced with nitrogen atoms), a quinoxalinyl group, a pyridazinyl group, a triazinyl group, a quinazolinyl group, and a phthalazinyl group); a fluorinated hydrocarbon group (for example, a fluoromethyl group, trifluoromethyl group, a pentafluoroethyl group and a pentafluorophenyl group); a cyano group; a nitro group; a tosyl group; and an acyl group.

Moreover, these substituents may be further substituted by the aforesaid substituent. Further, a plurality of these substituents may be bonded with each other to form a ring.

Specific examples of a luminescent metal complex according to the present invention are indicated in the following. However, the present invention is not limited to them, as long as the compound forms an exciplex with a host compound to be combined.

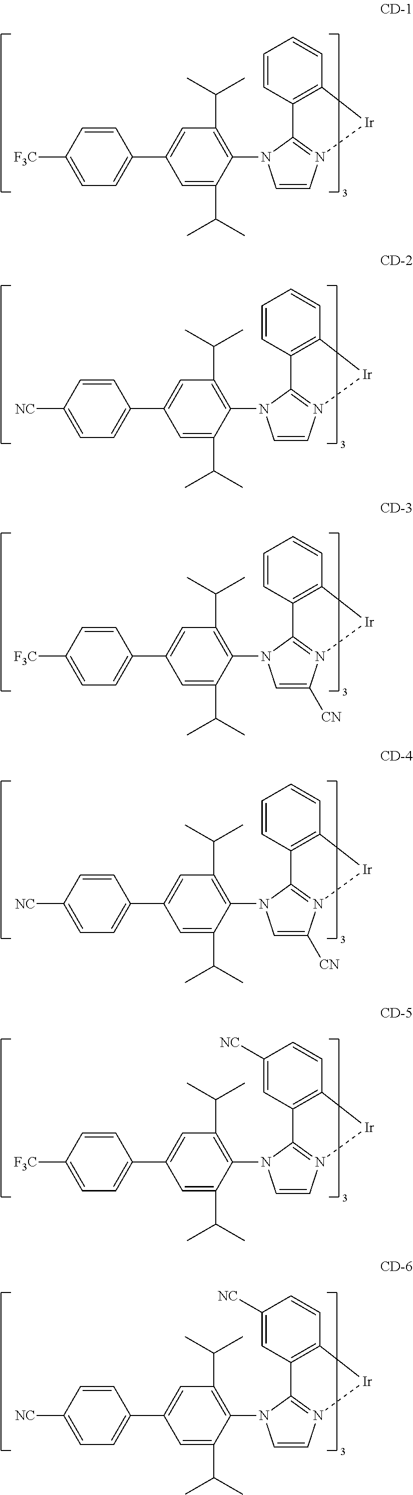

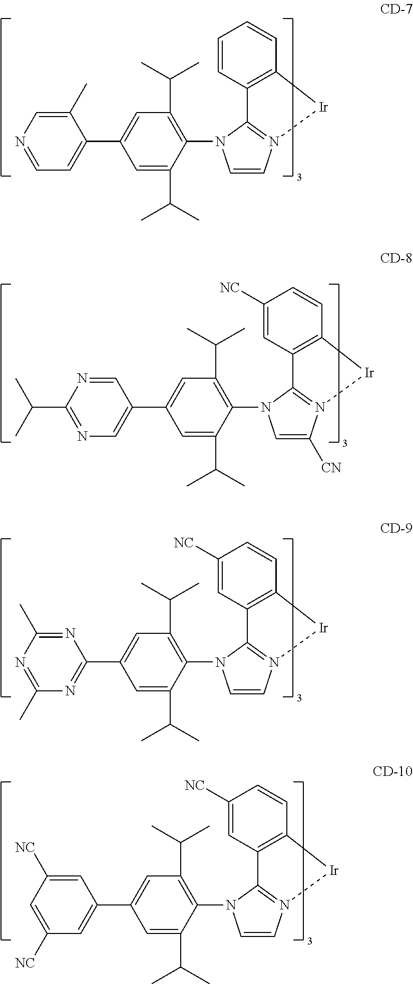

### <<Host Compound>>

A host compound according to the present invention is a compound capable of forming an exciplex with a phosphorescent metal complex. In the following, it will be described a host compound according to a first embodiment in which a host compound forms an exciplex with a phosphorescent metal complex. Further, it will be described a host compound according to a second embodiment in which at least two kinds of host compounds are contained, and at least one kind of host compound is capable of forming an exciplex with the phosphorescent metal complex, and a plurality of the other kind of host compounds are capable of forming an exciplex with each other. Further, it will be described a host compound according to a third embodiment in which a host compound emits thermally activated delayed fluorescence (TADF).

### <Host Compound According to First Embodiment>

In order to from an exciplex with a LUMO orbital of a phosphorescent metal complex, it is preferable that a host compound according to a first embodiment has an electron donating property in a partial structure that forms a HOMO orbital. Examples thereof are partial structures of carbazole, allylamine, carboline, indocarbazole, and indoloindole.

Specific examples of a host compound according to the first embodiment of the present invention are indicated in the following, however, the present invention is not limited to them.

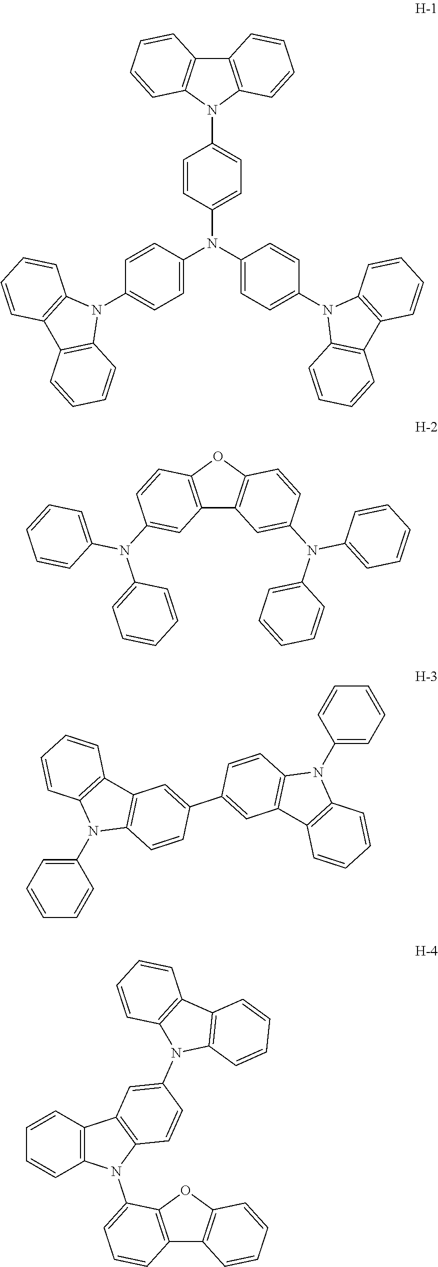 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc(N(c2ccccc2)c2ccc3oc4ccc(N(c5ccccc5)c5ccccc5)cc4c3c2)cc1 ; c1ccc(-n2c3ccccc3c3cc(-c4ccc5c(c4)c4ccccc4n5-c4ccccc4)ccc32)cc1 ; c1ccc2c(c1)oc1c(-n3c4ccccc4c4cc(-n5c6ccccc6c6ccccc65)ccc43)cccc12]

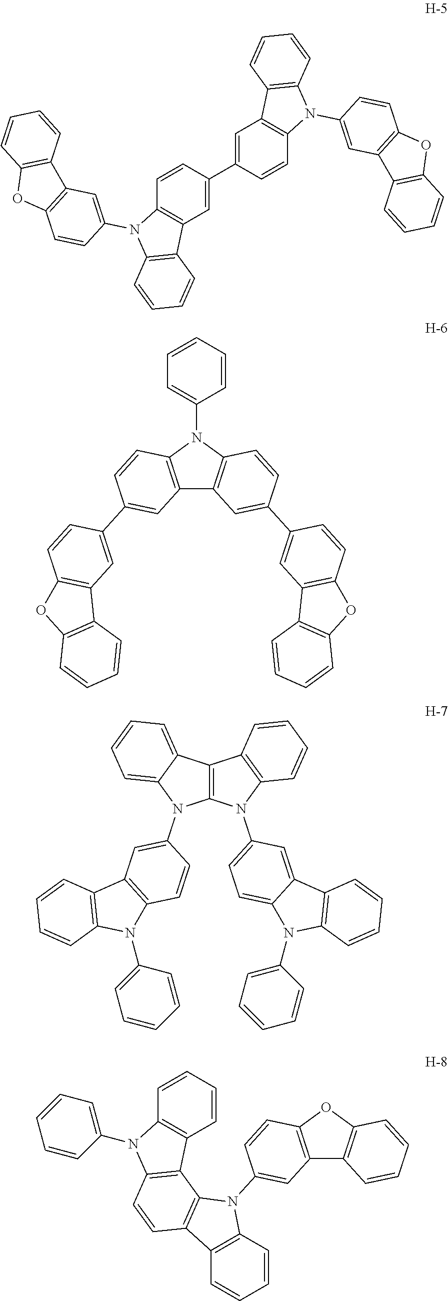

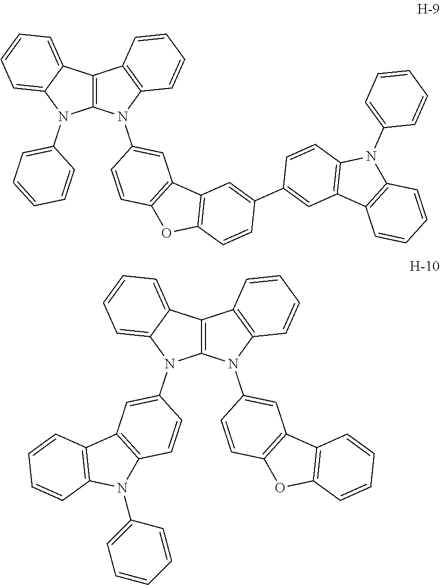

### <Host Compound According to Second Embodiment>

Host compounds according to a second embodiment are constituted with two kinds of host compounds. The following combination of two kinds of host compounds is preferable. One of the host compounds forms an exciplex with the phosphorescent metal complex, and a plurality of other kind of host compounds form an exciplex with each other.

The exciplex formed with the host compound according to the second embodiment has a small gap between the lowest triplet excited state level and the lowest singlet excited state level. A reverse intersystem crossing phenomenon is observed between these two states.

A combination of host compounds that form an exciplex is not limited in particular. Examples are combinations of the compounds described in Adv. Mater., 2014, 26, 4730-4734; and combinations of the compounds described in Adv. Mater., 2015, 27, 2378-2383.

Specific examples of a host compound according to a second embodiment of the present invention are indicated in the following, however, the present invention is not limited to them.

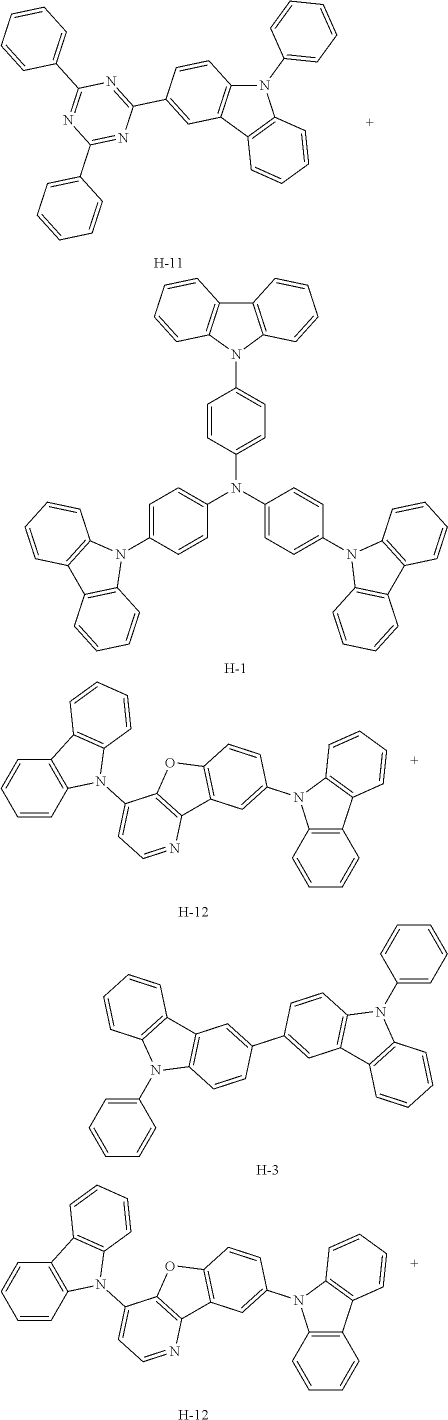

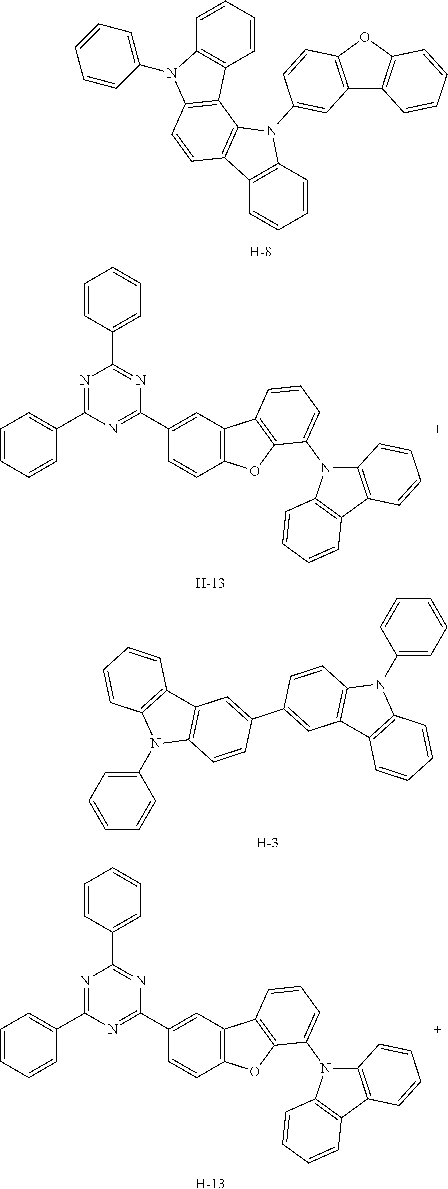

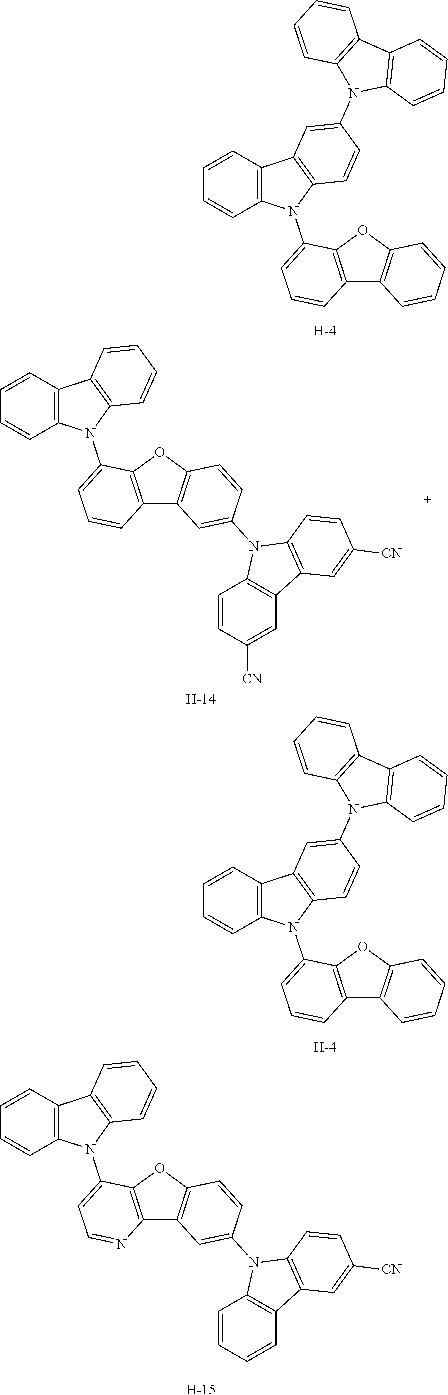

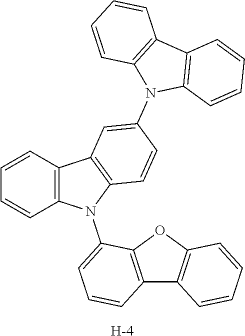

### <Host Compound According to Third Embodiment>

A host compound according to a third embodiment is a compound exhibiting thermally activated delayed fluorescence (TADF).

Since the host compound according to the third embodiment exhibits thermally activated delayed fluorescence, the host compound has a small gap between the lowest triplet excited state level and the lowest singlet excited state level. A reverse intersystem crossing phenomenon is observed between the two states.

Thermally activated delayed fluorescence is described in pages 261 to 268 of “Device Property of Organic Semiconductor” (Edited by Chihaya ADACHI, published from Kodansha). In this literature, it is described the following. When the energy difference ΔE between the lowest singlet excited state level and the lowest triplet excited state level of the fluorescent material, the reverse energy transfer from the excited triplet state to the excited singlet state, which is a phenomenon usually occurring in low transition probability, occurs with high efficiency to result in exhibiting thermally activated delayed fluorescence (TADF). Further, a generation mechanism of thermally activated delayed fluorescence is described in FIG. 10.38. A host compound according to a third embodiment is a compound that exhibits thermally activated delayed fluorescence generated by the above-described mechanism. Generation of delayed fluorescence may be confirmed with transient PL measurement.

Transient PL is a method of measuring the attenuation behavior (transient characteristic) of PL emission after exciting by irradiating a sample with a pulse laser and stopping irradiation. PL emission in a TADF material is classified into a luminescent component from a singlet exciton generated by the first PL excitation and a luminescent component from a singlet exciton generated via a triplet exciton. The lifetime of singlet excitons generated by the first PL excitation is on the nanosecond order and is very short. Therefore, the light emission from the singlet exciton attenuates quickly after irradiation with the pulse laser.

On the other hand, the delayed fluorescence gently decreases due to light emission from a singlet exciton generated via a triplet exciton having a long lifetime. Thus, there is a large difference in time between the light emission from the singlet exciton generated by the first PL excitation and the emission from the singlet exciton generated via the triplet exciton. The host compound according to the third embodiment is a compound having such a luminescent component derived from the delayed fluorescence.

The compound that exhibits the delayed fluorescence is not limited in particular. Examples thereof are compounds described in Adv. Mater. 2014, DOI:10. 1002/adma. 201402532.

Specific examples of a host compound according to a third embodiment of the present invention are indicated in the following, however, the present invention is not limited to them.

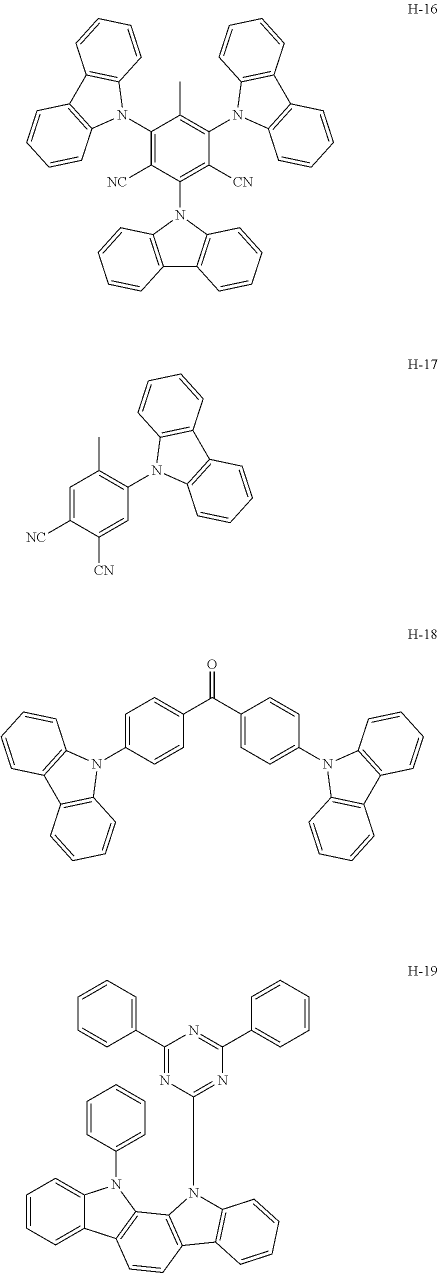 [SMILES: Cc1c(-n2c3ccccc3c3ccccc32)c(C#N)c(-n2c3ccccc3c3ccccc32)c(C#N)c1-n1c2ccccc2c2ccccc21 ; Cc1cc(C#N)c(C#N)cc1-n1c2ccccc2c2ccccc21 ; O=C(c1ccc(-n2c3ccccc3c3ccccc32)cc1)c1ccc(-n2c3ccccc3c3ccccc32)cc1 ; c1ccc(-c2nc(-c3ccccc3)nc(-n3c4ccccc4c4ccc5c6ccccc6n(-c6ccccc6)c5c43)n2)cc1]

As described above, “the luminescent metal complex” and “the host compound” contained in the luminescent thin film according to the present invention have been described by dividing into a plurality of embodiments. Any combination of “the luminescent metal complex” and “the host compound” may be used. Further, “the luminescent metal complex” of the above-described plurality of embodiments may be used in combination, and “the host compound” of the above-described plurality of embodiments may be used together.

The luminescent thin film of the present invention may be applied to various products. For example, it can be applied to an organic electroluminescent element and an organic thin film solar cell, which will be described later. The luminescent thin film of the present invention may further contain known substances commonly used when applied to each product besides the above-mentioned “luminescent metal complex” and “host compound”.

### <<Constituting Layers of Organic Electroluminescent Element>>

Representative element constitutions used for an organic EL element of the present invention are as follows, however, the present invention is not limited to these.

(1) Anode/light emitting layer/cathode
(2) Anode/light emitting layer/electron transport layer/cathode
(3) Anode/hole transport layer/light emitting layer/cathode
(4) Anode/hole transport layer/light emitting layer/electron transport layer/cathode
(5) Anode/hole transport layer/light emitting layer/electron transport layer/electron injection layer/cathode
(6) Anode/hole injection layer/hole transport layer/light emitting layer/electron transport layer/cathode
(7) Anode/hole injection layer/hole transport layer/(electron blocking layer/) light emitting layer/(hole blocking layer/) electron transport layer/electron injection layer/cathode

Among these, the embodiment (7) is preferably used. However, the present invention is not limited to this.

The light emitting layer according to the present invention is composed of one layer or a plurality of layers. When a plurality of layers are employed, a non-light emitting intermediate layer may be placed between the light emitting layers.

According to necessity, a hole blocking layer (it is also called as a hole barrier layer) or an electron injection layer (it is also called as a cathode buffer layer) may be provided between the light emitting layer and the cathode. Further, an electron blocking layer (it is also called as an electron barrier layer) or an hole injection layer (it is also called as an anode buffer layer) may be provided between the light emitting layer and the anode.

An electron transport layer according to the present invention is a layer having a function of transporting an electron. An electron transport layer includes an electron injection layer, and a hole blocking layer in a broad sense. Further, an electron transport layer unit may be composed of plural layers.

A hole transport layer according to the present invention is a layer having a function of transporting a hole. A hole transport layer includes a hole injection layer, and an electron blocking layer in a broad sense. Further, a hole transport layer unit may be composed of plural layers.

In the representative element constitutions as described above, the layers eliminating an anode and a cathode are also called as “organic layers”.

### (Tandem Structure)

An organic EL element of the present invention may be so-called a tandem structure element in which plural light emitting units each containing at least one light emitting are laminated.

Representative examples of an element constitution having a tandem structure are as follows.

Anode/first light emitting unit/second light emitting unit/third light emitting unit/cathode; and

Anode/first light emitting unit/intermediate layer/second light emitting unit/intermediate layer/third light emitting unit/cathode.

Here, the aforesaid first light emitting unit, second light emitting unit, and third light emitting unit may be the same or different. It is possible that two light emitting units are the same and the remaining one light emitting unit is different.

In addition, the third light emitting unit may not be provided. Otherwise, a further light emitting unit or a further intermediate layer may be provided between the third light emitting unit and the electrode.

The plural light emitting units each may be laminated directly or they may be laminated through an intermediate layer. Examples of an intermediate layer are: an intermediate electrode, an intermediate conductive layer, a charge generating layer, an electron extraction layer, a connecting layer, and an intermediate insulating layer. Known composing materials may be used as long as they can form a layer which has a function of supplying an electron to an adjacent layer to the anode, and a hole to an adjacent layer to the cathode.

Examples of a material used in an intermediate layer are: conductive inorganic compounds such as ITO (indium tin oxide), IZO (indium zinc oxide), ZnO₂, TiN, ZrN, HfN, TiOx, VOx, CuI, InN, GaN, CuAlO₂, CuGaO₂, SrCu₂O₂, LaB₆, RuO₂, and Al; a two-layer film such as Au/Bi₂O₃; a multi-layer film such as SnO₂/Ag/SnO₂, ZnO/Ag/ZnO, Bi₂O₃/Au/Bi₂O₃, TiO₂/TiN/TiO₂, and TiO₂/ZrN/TiO₂; fullerene such as Co; and a conductive organic layer such as oligothiophene, metal phthalocyanine, metal-free phthalocyanine, metal porphyrin, and metal-free porphyrin. The present invention is not limited to them.

Examples of a preferable constitution in the light emitting unit are the constitutions of the above-described (1) to (7) from which an anode and a cathode are removed. However, the present invention is not limited to them.

Specific examples of a tandem type organic EL element are described in: U.S. Pat. No. 6,337,492, U.S. Pat. No. 7,420,203, U.S. Pat. No. 7,473,923, U.S. Pat. No. 6,872,472, U.S. Pat. No. 6,107,734, U.S. Pat. No. 6,337,492, WO 2005/009087, JP-A 2006-228712, JP-A 2006-24791, JP-A 2006-49393, JP-A 2006-49394, JP-A 2006-49396, JP-A 2011-96679, JP-A 2005-340187, JP Patent 4711424, JP Patent 3496681, JP Patent 3884564, JP Patent 4213169, JP-A 2010-192719, JP-A 2009-076929, JP-A 2008-078414, JP-A 2007-059848, JP-A 2003-272860, JP-A 2003-045676, and WO 2005/094130. The constitutions of the elements and the composing materials are described in these documents, however, the present invention is not limited to them.

Each layer that constitutes an organic EL element of the present invention will be described in the following.

### <<Light Emitting Layer>>

A light emitting layer used in the present invention is a layer which provides a place of emitting light via an exciton produce by recombination of electrons and holes injected from an electrode or an adjacent layer. The light emitting portion may be either within the light emitting layer or at an interface between the light emitting layer and an adjacent layer thereof.

The light emitting layer according to the present invention is constituted with the aforesaid “luminescent thin film”.

The constitution of the light emitting layer according to the present invention is not particularly limited as long as it satisfies the requirements of the luminescent thin film defined in the present invention.

A total thickness of the light emitting layer is not particularly limited. However, in view of layer homogeneity, preventing unnecessary high voltage during light emission, and stability of the emitted light color against a drive electric current, the total layer thickness is preferably adjusted to be in the range of 2 nm to 5 μm, more preferably, it is in the range of 2 to 500 nm, and still most preferably, it is in the range of 5 to 200 nm.

Each light emitting layer of the present invention is preferably adjusted to be in the range of 2 nm to 1 μm, more preferably, it is adjusted to be in the range of 2 to 200 nm, and still most preferably, it is adjusted to be in the range of 3 to 150 nm.

The light emitting layer according to the present invention is constituted with the aforesaid “luminescent metal complex” and “host compound”.

The light emitting layer according to the present invention may further contain the following compounds described below within the range of not preventing the effect of the present invention: (1) light emitting dopant (such as (1.1) phosphorescence emitting dopant, and (1.2) fluorescence emitting dopant); and (2) host compound.

### (1) Light Emitting Dopant

The light emitting dopant used in the present invention will be described.

As a light emitting dopant: a phosphorescence emitting dopant (also referred to as a phosphorescent dopant and a phosphorescence emitting compound) and a fluorescence emitting dopant (also referred to as a fluorescent dopant and a fluorescent compound) may be used.

A plurality of light emitting dopants of the present invention may be used. It may be used a combination of dopants each having a different structure, or a combination of a fluorescence emitting compound and a phosphorescence emitting compound. Any required emission color will be obtained by this.

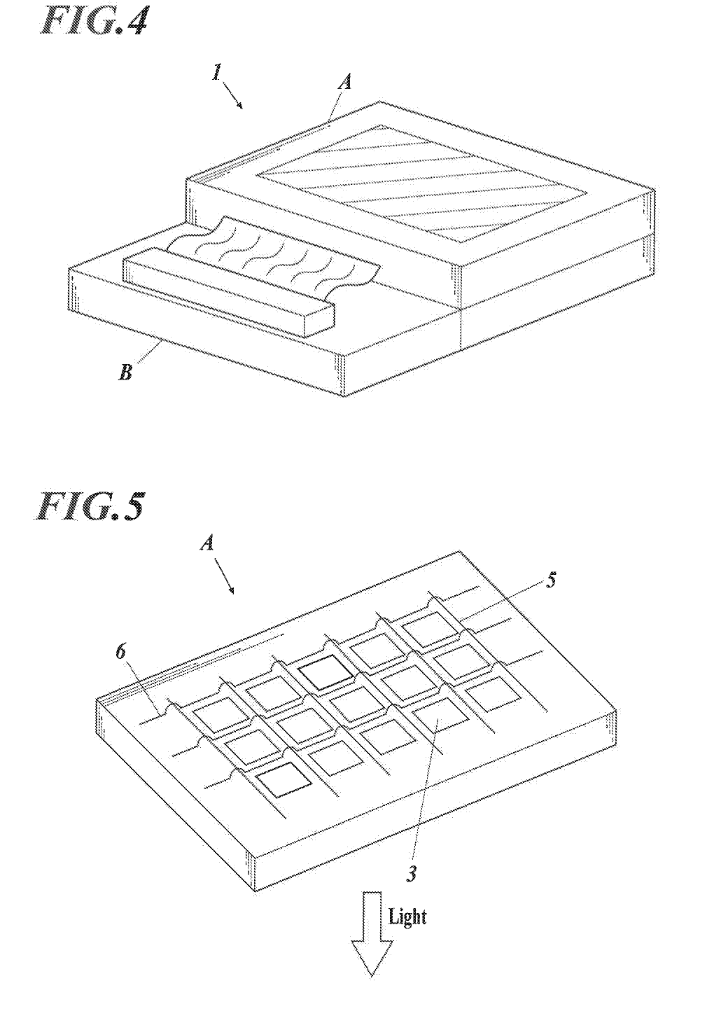

Color of light emitted by an organic EL element or a luminescent thin film of the present invention is specified as follows. In FIG. 4.16 on page 108 of “Shinpen Shikisai Kagaku Handbook (New Edition Color Science Handbook)” (edited by The Color Science Association of Japan, Tokyo Daigaku Shuppan Kai, 1985), values determined via Spectroradiometer CS-1000 (produced by Konica Minolta, Inc.) are applied to the CIE chromaticity coordinate, whereby the color is specified.

In the present invention, it is preferable that the organic EL element of the present invention exhibits white emission by incorporating one or plural light emitting layers containing plural light emitting dopants having different emission colors.

The combination of light emitting dopants producing white is not specifically limited. It may be cited, for example, combinations of: blue and orange; and blue, green and red.

A white color in the organic EL element of the present invention is not specifically limited. It may be a white color approaching to an orange color, or may be a white color approaching to an orange color.

It is preferable that “white” in the organic EL element of the present invention exhibits chromaticity in the CIE 1931 Color Specification System at 1,000 cd/m² in the region of x=0.39±0.09 and y=0.38±0.08, when measurement is done to 2-degree viewing angle front luminance via the aforesaid method.

### (1.1) Phosphorescence Emitting Dopant

A phosphorescence emitting dopant according to the present invention will be described. Hereafter, it may be called as “a phosphorescent dopant”.

The phosphorescent dopant used in the present invention is a compound which is observed emission from an excited triplet state thereof. Specifically, it is a compound which emits phosphorescence at a room temperature (25° C.) and exhibits a phosphorescence quantum yield of at least 0.01 at 25° C. The phosphorescence quantum yield is preferably at least 0.1.

The phosphorescence quantum yield in the present invention will be determined via a method described in page 398 of Bunko II of Dai 4 Han Jikken Kagaku Koza 7 (Spectroscopy II of 4th Edition Lecture of Experimental Chemistry 7) (1992, published by Maruzen Co. Ltd.). The phosphorescence quantum yield in a solution will be determined using appropriate solvents. However, it is only necessary for the phosphorescent dopant of the present invention to exhibit the above phosphorescence quantum yield (0.01 or more) using any of the appropriate solvents.

Two kinds of principles regarding emission of a phosphorescent dopant are cited. One is an energy transfer-type, wherein carriers recombine on a host compound on which the carriers are transferred to produce an excited state of the host compound, and then via transfer of this energy to a phosphorescent dopant, emission from the phosphorescent dopant is realized. The other is a carrier trap-type, wherein a phosphorescent dopant serves as a carrier trap and then carriers recombine on the phosphorescent dopant to generate emission from the phosphorescent dopant. In each case, the excited state energy level of the phosphorescent dopant is required to be lower than that of the host compound.

A phosphorescent dopant that may be used in the present invention is suitably selected and employed from the known materials used for a light emitting layer for an organic EL element.

Examples of a known phosphorescent dopant are compounds described in the following publications.

Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991, WO 2008/101842, WO 2003/040257, US 2006/835469, US 2006/0202194, US 2007/0087321, US 2005/0244673, Inorg. Chem. 40, 1704 (2001), Chem. Mater. 16, 2480 (2004), Adv. Mater. 16, 2003 (2004), Angew. Chem. Int. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), WO 2009/050290, WO 2002/015645, WO 2009/000673, US 2002/0034656, U.S. Pat. No. 7,332,232, US 2009/0108737, US 2009/0039776, U.S. Pat. No. 6,921,915, U.S. Pat. No. 6,687,266, US 2007/0190359, US 2006/0008670, US 2009/0165846, US 2008/0015355, U.S. Pat. No. 7,250,226, U.S. Pat. No. 7,396,598, US 2006/0263635, US 2003/0138657, US 2003/0152802, U.S. Pat. No. 7,090,928, Angew. Chem. Int. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2002/002714, WO 2006/009024, WO 2006/056418, WO 2005/019373, WO 2005/123873, WO 2005/123873, WO 2007/004380, WO 2006/082742, US 2006/0251923, US 2005/0260441, U.S. Pat. No. 7,393,599, U.S. Pat. No. 7,534,505, U.S. Pat. No. 7,445,855, US 2007/0190359, US 2008/0297033, U.S. Pat. No. 7,338,722, US 2002/0134984, and U.S. Pat. No. 7,279,704, US 2006/098120, US 2006/103874, WO 2005/076380, WO 2010/032663, WO 2008/140115, WO 2007/052431, WO 2011/134013, WO 2011/157339, WO 2010/086089, WO 2009/113646, WO 2012/020327, WO 2011/051404, WO 2011/004639, WO 2011/073149, JP-A 2012-069737, JP Application No. 2011-181303, JP-A 2009-114086, JP-A 2003-81988, JP-A 2002-302671 and JP-A 2002-363552.

Among them, preferable phosphorescent dopants are organic metal complexes containing Ir as a center metal. More preferable are complexes containing at least one coordination mode selected from a metal-carbon bond, a metal-nitrogen bond, a metal-oxygen bond and a metal-sulfur bond.

### (1.2) Fluorescence Emitting Dopant

A fluorescence emitting dopant used in the present invention will be described. Hereafter, it may be called as “a fluorescent dopant”.

A fluorescence emitting dopant used in the present invention is a compound which is observed emission from an excited singlet state thereof. The compound is not limited as long as emission from an excited singlet state is observed.

As specific fluorescent dopants usable in the present invention, listed are compounds such as: an anthracene derivative, a pyrene derivative, a chrysene derivative, a fluoranthene derivative, a perylene derivative, a fluorene derivative, an arylacetylene derivative, a styrylarylene derivative, a styrylamine derivative, an arylamine derivative, a boron complex, a coumarin derivative, a pyran derivative, a cyanine derivative, a croconium derivative, a squarylium derivative, an oxobenzanthracene derivative, a fluorescein derivative, a rhodamine derivative, a pyrylium derivative, a perylene derivative, a polythiophene derivative, and a rare earth complex compound.

In recent years, light emitting dopants utilizing delayed fluorescence was developed. These dopants may be used.

Specific examples of a light emitting dopant utilizing delayed fluorescence are compounds described in: WO 2011/156793, JP-A 2011-213643, and JP-A 2010-93181. However, the present invention is not limited to them.

### (2) Host Compound

A host compound used in the present invention is a compound which mainly plays a role of injecting or transporting a charge in a light emitting layer. In an organic EL element, an emission from the host compound itself is substantially not observed.

Preferably, it is a compound exhibiting a phosphorescence emission yield of less than 0.1 at a room temperature (25° C.), more preferably a compound exhibiting a phosphorescence emission yield of less than 0.01.

It is preferable that the excited energy level of the host compound is higher than the excited energy level of the light emitting dopant contained in the same layer.

Host compounds may be used singly or may be used in combination of two or more compounds. By using a plurality of host compounds, it is possible to adjust transfer of charge, thereby it is possible to achieve an organic EL element of high efficiency.

A host compound used in a light emitting layer of the present invention is not specifically limited. A known compound previously used in an organic EL element may be used. It may be a compound having a low molecular weight, or a polymer having a high molecular weight. Further, it may be a compound having a reactive group such as a vinyl group or an epoxy group.

As a known host compound, preferably, it has a hole transporting ability or an electron transporting ability, as well as preventing elongation of an emission wavelength. In addition, from the viewpoint of stably driving an organic EL element at high temperature, it is preferable that a host compound has a high glass transition temperature (Tg) of 90° C. or more, more preferably, a Tg of 120° C. or more.

Here, a glass transition temperature (Tg) is a value obtained using DSC (Differential Scanning Colorimetry) based on the method in conformity to JIS-K-7121.

As specific examples of a known host compound used in an organic EL element of the present invention, the compounds described in the following Documents are cited. However, the present invention is not to them.

Japanese patent application publication (JP-A) Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837; US Patent Application Publication (US) Nos. 2003/0175553, 2006/0280965, 2005/0112407, 2009/0017330, 2009/0030202, 2005/0238919; WO 2001/039234, WO 2009/021126, WO 2008/056746, WO 2004/093 207, WO 2005/089025, WO 2007/063796, WO 2007/063754, WO 2004/107822, WO 2005/030900, WO 2006/114966, WO 2009/086028, WO 2009/003898, WO 2012/023947, JP-A 2008-074939, JP-A 2007-254297, and EP 2034538.

### <<Electron Transport Layer>>

An electron transport layer of the present invention is composed of a material having a function of transferring an electron. It is only required to have a function of transporting an injected electron from a cathode to a light emitting layer.

A total layer thickness of the electron transport layer used in the present invention is not specifically limited, however, it is generally in the range of 2 nm to 5 μm, and preferably, it is in the range of 2 to 500 nm, and more preferably, it is in the range of 5 to 200 nm.

In an organic EL element, it is known that there occurs interference between the light directly taken from the light emitting layer and the light reflected at the electrode located at the opposite side of the electrode from which the light is taken out at the moment of taking out the light which is produced in the light emitting layer. When the light is reflected at the cathode, it is possible to use effectively this interference effect by suitably adjusting the total thickness of the electron transport layer in the range of 5 nm to 1 μm.

On the other hand, the voltage will be increased when the layer thickness of the electron transport layer is made thick. Therefore, especially when the layer thickness is large, it is preferable that the electron mobility in the electron transport layer is 10⁻⁵ cm²/Vs or more.

As a material used for an electron transport layer (hereafter, it is called as an electron transport material), it is only required to have either a property of ejection or transport of electrons, or a barrier to holes. Any of the conventionally known compounds may be selected and they may be employed.

Cited examples thereof include: a nitrogen-containing aromatic heterocyclic derivative (a carbazole derivative, an azacarbazole derivative (a compound in which one or more carbon atoms constituting the carbazole ring are substitute with nitrogen atoms), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, and a benzothiazole derivative); a dibenzofuran derivative, a dibenzothiophene derivative, a silole derivative; and an aromatic hydrocarbon ring derivative (a naphthalene derivative, an anthracene derivative and a triphenylene derivative).

Further, metal complexes having a ligand of a 8-quinolinol structure or dibnenzoquinolinol structure such as tris(8-quinolinol)aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which a central metal of the aforesaid metal complexes is substituted by In, Mg, Cu, Ca, Sn, Ga or Pb, may be also utilized as an electron transport material.

Further, a metal-free or metal phthalocyanine, or a compound whose terminal is substituted by an alkyl group or a sulfonic acid group, may be preferably utilized as an electron transport material. A distyryl pyrazine derivative, which is exemplified as a material for a light emitting layer, may be used as an electron transport material. Further, in the same manner as used for a hole injection layer and a hole transport layer, an inorganic semiconductor such as an n-type Si and an n-type SiC may be also utilized as an electron transport material.

A polymer material introducing these compounds in the polymer side-chain or a polymer material having any one of these substance in a polymer main chain may be also used.

In an electron transport layer used in the present invention, it is possible to form an electron transport layer of a higher n property (electron rich) by doping with a dope material as a guest material. As examples of a dope material, listed are: metal compounds such as metal complexes and metal halides, and other n-type dopants. As specific examples of an electron transport layer having such constitution, listed are those described in each of JP-A Nos. 4-297076, 10-270172, 2000-196140, 2001-102175, as well as in J. Appl. Phys., 95, 5773 (2004).

Examples of a preferable known electron transport material used in an organic EL element of the present invention are compounds described in the following publications. However, the present invention is not limited to them.

U.S. Pat. No. 6,528,187, U.S. Pat. No. 7,230,107, US 2005/0025993, US 2004/0036077, US 2009/0115316, US 2009/0101870, US 2009/0179554, WO 2003/060956, WO 2008/132085, Appl. Phys. Lett. 75, 4 (1999), Appl. Phys. Lett. 79, 449 (2001), Appl. Phys. Lett. 81, 162 (2002), Appl. Phys. Lett. 81, 162 (2002), Appl. Phys. Lett. 79, 156 (2001), U.S. Pat. No. 7,964,293, US 2009/030202, WO 2004/080975, WO 2004/063159, WO 2005/085387, WO 2006/067931, WO 2007/086552, WO 2008/114690, WO 2009/069442, WO 2009/066779, WO 2009/054253, WO 2011/086935, WO 2010/150593, WO 2010/047707, EP 2311826, JP-A 2010-251675, JP-A 2009-209133, JP-A 2009-124114, JP-A 2008-277810, JP-A 2006-156445, JP-A 2005-340122, JP-A 2003-45662, JP-A 2003-31367, JP-A 2003-282270, and WO 2012/115034.

Examples of a preferable electron transport material are: a pyridine derivative, a pyrimidine derivative, a pyrazine derivative, a triazine derivative, a dibenzofuran derivative, a dibenzothiophene derivative, a carbazole derivative, an azacarbazole derivative, and a benzimidazole derivative.

An electron transport material may be used singly or may be used in combination of plural compounds.

### <<Hole Blocking Layer>>

A hole blocking layer is a layer having a function of an electron transport layer in a broad meaning. Preferably, it contains a material having a function of transporting an electron, and having very small ability of transporting a hole. It will improve the recombination probability of an electron and a hole by blocking a hole while transporting an electron.

Further, a composition of an electron transport layer described above may be appropriately utilized as a hole blocking layer of the present invention when needed.

A hole blocking layer placed in an organic EL element of the present invention is preferably arranged at a location adjacent to the light emitting layer on the cathode side.

A thickness of a hole blocking layer used in the present invention is preferably in the range of 3 to 100 nm, and more preferably, in the range of 5 to 30 nm.

With respect to a material used for a hole blocking layer, the material used in the aforesaid electron transport layer is suitably used, and further, the material used as the aforesaid host compound is also suitably used for a hole blocking layer.

### <<Electron Injection Layer>>

An electron injection layer (it is also called as “a cathode buffer layer”) used in the present invention is a layer which is arranged between a cathode and a light emitting layer to decrease a driving voltage and to improve an emission luminance. An example of an electron injection layer is detailed in volume 2, chapter 2 “Electrode materials” (pp. 123-166) of “Organic EL Elements and Industrialization Front thereof (Nov. 30, 1998, published by N.T.S. Co. Ltd.)”.

In the present invention, an electron injection layer is provided according to necessity, and as described above, it is placed between a cathode and a light emitting layer, or between a cathode and an electron transport layer.

An electron injection layer is preferably a very thin film. The layer thickness thereof is preferably in the range of 0.1 to 5 nm depending on the materials used.

An election injection layer is detailed in JP-A Nos. 6-325871, 9-17574, and 10-74586. Examples of a material preferably used in an election injection layer include: a metal such as strontium and aluminum; an alkaline metal compound such as lithium fluoride, sodium fluoride, or potassium fluoride; an alkaline earth metal compound such as magnesium fluoride; a metal oxide such as aluminum oxide; and a metal complex such as lithium 8-hydroxyquinolate (Liq). It is possible to use the aforesaid electron transport materials.

The aforesaid materials may be used singly or plural kinds may be used together in an election injection layer.

### <<Hole Transport Layer>>

In the present invention, a hole transport layer contains a material having a function of transporting a hole. A hole transport layer is only required to have a function of transporting a hole injected from an anode to a light emitting layer.

The total layer thickness of a hole transport layer of the present invention is not specifically limited, however, it is generally in the range of 5 nm to 5 μm, preferably in the range of 2 to 500 nm, and more preferably in the range of 5 nm to 200 nm.

A material used in a hole transport layer (hereafter, it is called as a hole transport material) is only required to have any one of properties of injecting and transporting a hole, and a barrier property to an electron. A hole transport material may be suitably selected from the conventionally known compounds.

Examples of a hole transport material include:

a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene derivative of anthracene or naphthalene, a fluorene derivative, a fluorenone derivative, polyvinyl carbazole, a polymer or an oligomer containing an aromatic amine in a side chain or a main chain, polysilane, and a conductive polymer or an oligomer (e.g., PEDOT: PSS, an aniline type copolymer, polyaniline and polythiophene).

Examples of a triarylamine derivative include: a benzidine type represented by α-NPD, a star burst type represented by MTDATA, a compound having fluorenone or anthracene in a triarylamine bonding core.

A hexaazatriphenylene derivative described in JP-A Nos. 2003-519432 and 2006-135145 may be also used as a hole transport material.

In addition, it is possible to employ an electron transport layer of a higher p property which is doped with impurities. As its example, listed are those described in each of JP-A Nos. 4-297076, 2000-196140, and 2001-102175, as well as in J. Appl. Phys., 95, 5773 (2004).

Further, it is possible to employ so-called p-type hole transport materials, and inorganic compounds such as p-type Si and p-type SiC, as described in JP-A No. 11-251067, and J. Huang et al. reference (Applied Physics Letters 80 (2002), p. 139). Moreover, an orthometal compounds having Ir or Pt as a center metal represented by Ir(ppy)₃ are also preferably used.

Although the aforesaid compounds may be used as a hole transport material, preferably used are: a triarylamine derivative, a carbazole derivative, an indolocarbazole derivative, an azatriphenylene derivative, an organic metal complex, a polymer or an oligomer incorporated an aromatic amine in a main chain or in a side chain.

Specific examples of a known hole transport material used in an organic EL element of the present invention are compounds in the aforesaid publications and in the following publications. However, the present invention is not limited to them.

Examples of a publication are: Appl. Phys. Lett. 69, 2160(1996), J. Lumin. 72-74, 985(1997), Appl. Phys. Lett. 78, 673(2001), Appl. Phys. Lett. 90, 183503(2007), Appl. Phys. Lett. 51, 913(1987), Synth. Met. 87, 171(1997), Synth. Met. 91, 209(1997), Synth. Met. 111, 421(2000), SID Symposium Digest, 37, 923(2006), J. Mater. Chem. 3, 319(1993), Adv. Mater. 6, 677(1994), Chem. Mater. 15, 3148(2003), US 2003/0162053, US 2002/0158242, US 2006/0240279, US 2008/0220265, U.S. Pat. No. 5,061,569, WO 2007/002683, WO 2009/018009, EP 650955, US 2008/0124572, US 2007/0278938, US 2008/0106190, US 2008/0018221, WO 2012/115034, JP-A 2003-519432, JP-A 2006-135145, and U.S. patent application Ser. No. 13/585,981.

A hole transport material may be used singly or may be used in combination of plural kinds of compounds.

### <<Electron Blocking Layer>>

An electron blocking layer is a layer provided with a function of a hole transport layer in a broad meaning. Preferably, it contains a material having a function of transporting a hole, and having very small ability of transporting an electron. It will improve the recombination probability of an electron and a hole by blocking an electron while transporting a hole.

Further, a composition of a hole transport layer described above may be appropriately utilized as an electron blocking layer of an organic EL element when needed.

An electron blocking layer placed in an organic EL element is preferably arranged at a location adjacent to the light emitting layer on the anode side.

A thickness of an electron blocking layer is preferably in the range of 3 to 100 nm, and more preferably, it is in the range of 5 to 30 nm.

With respect to a material used for an electron blocking layer, the material used in the aforesaid hole transport layer is suitably used, and further, the material used as the aforesaid host compound is also suitably used for an electron blocking layer.

### <<Hole Injection Layer>>

A hole injection layer (it is also called as “an anode buffer layer”) used in the present invention is a layer which is arranged between an anode and a light emitting layer to decrease a driving voltage and to improve an emission luminance. An example of a hole injection layer is detailed in volume 2, chapter 2 “Electrode materials” (pp. 123-166) of “Organic EL Elements and Industrialization Front thereof (Nov. 30, 1998, published by N.T.S. Co. Ltd.)”.

A hole injection layer of the present invention is provided according to necessity, and as described above, it is placed between an anode and a light emitting layer, or between an anode and a hole transport layer.

A hole injection layer is also detailed in JP-A Nos. 9-45479, 9-260062 and 8-288069. As materials used in the hole injection layer, it is cited the same materials used in the aforesaid hole transport layer.

Among them, preferable materials are: a phthalocyanine derivative represented by copper phthalocyanine; a hexaazatriphenylene derivative described in JP-A Nos. 2003-519432 and 2006-135145; a metal oxide represented by vanadium oxide; a conductive polymer such as amorphous carbon, polyaniline (or called as emeraldine) and polythiophene; an orthometalated complex represented by tris(2-phenylpyridine) iridium complex; and a triarylamine derivative.

The aforesaid materials used in the hole injection layer may be used singly or plural kinds may be co-used.

### <<Ingredient>>

The aforesaid organic layer of the present invention may further contain other ingredient.

Examples of an ingredient are: halogen elements such as bromine, iodine and chlorine, and a halide compound; and a compound, a complex and a salt of an alkali metal, an alkaline earth metal and a transition metal such as Pd, Ca and Na.

Although a content of an ingredient may be arbitrarily decided, preferably, it is 1,000 ppm or less based on the total mass of the layer containing the ingredient, more preferably, it is 500 ppm or less, and still more preferably, it is 50 ppm or less.

In order to improve a transporting property of an electron or a hole, or to facilitate energy transport of an exciton, the content of the ingredient is not necessarily within these ranges.

### <<Forming Method of Organic Layers>>

Forming methods of organic layers according to the present invention (hole injection layer, hole transport layer, light emitting layer, hole blocking layer, electron transport layer, and electron injection layer) will be described.

Forming methods of organic layers according to the present invention are not specifically limited. They may be formed by using a known method such as a vacuum vapor deposition method and a wet method (it may be called as a wet process).

It is preferable that the organic layers are formed with a wet process. That is, it is preferable to produce the organic EL element with a wet process. By producing the organic EL element with a wet process, a homogeneous film (coating film) is easily obtained, and it is possible to achieve the effect that pinholes are less likely generated. Here, the film (coating film) is in a state of being dried after coating with a wet process.

Examples of a wet process include: a spin coating method, a cast method, an inkjet method, a printing method, a die coating method, a blade coating method, a roll coating method, a spray coating method, a curtain coating method, and a LB method (Langmuir Blodgett method). From the viewpoint of getting a uniform thin layer with high productivity, preferable are method highly appropriate to a roll-to-roll method such as a die coating method, a roll coating method, an inkjet method, and a spray coating method.

Examples of a liquid medium to dissolve or to disperse a material for organic layers according to the present invention include: ketones such as methyl ethyl ketone and cyclohexanone; aliphatic esters such as ethyl acetate; halogenated hydrocarbons such as dichlorobenzene; aromatic hydrocarbons such as toluene, xylene, mesitylene, and cyclohexylbenzene; aliphatic hydrocarbons such as cyclohexane, decalin, and dodecane; organic solvents such as DMF and DMSO.

These will be dispersed with a dispersion method such as an ultrasonic dispersion method, a high shearing dispersion method and a media dispersion method.

A different film forming method may be applied to every organic layer. When a vapor deposition method is adopted for forming each layer, the vapor deposition conditions may be changed depending on the compounds used. Generally, the following ranges are suitably selected for the conditions, heating temperature of boat: 50 to 450° C., level of vacuum: 10⁶ to 10⁻² Pa, vapor deposition rate: 0.01 to 50 nm/sec, temperature of substrate: −50 to 300° C., and layer thickness: 0.1 nm to 5 μm, preferably 5 to 200 nm.

Formation of organic layers used in the present invention is preferably continuously carried out from a hole injection layer to a cathode with one time vacuuming. It may be taken out on the way, and a different layer forming method may be employed. In that case, the operation is preferably done under a dry inert gas atmosphere.

### <<Anode>>

As an anode of an organic EL element, a metal having a large work function (4 eV or more, preferably, 4.5 eV or more), an alloy, and a conductive compound and a mixture thereof are utilized as an electrode substance. Specific examples of an electrode substance are: metals such as Au; transparent conductive materials such as CuI, indium tin oxide (ITO), SnO₂, and ZnO. Further, a material such as IDIXO (In₂O₃—ZnO), which may form an amorphous and transparent electrode, may also be used.

As for an anode, these electrode substances may be made into a thin layer by a method such as a vapor deposition method or a sputtering method; followed by making a pattern of a desired form by a photolithography method. Otherwise, when the requirement of pattern precision is not so severe (about 100 μm or more), a pattern may be formed through a mask of a desired form at the time of layer formation with a vapor deposition method or a sputtering method using the aforesaid material.

Alternatively, when a coatable substance such as an organic conductive compound is employed, it is possible to employ a wet film forming method such as a printing method or a coating method. When emitted light is taken out from the anode, the transmittance is preferably set to be 10% or more. A sheet resistance of the anode is preferably a few hundred Ω/sq or less.

Further, although a layer thickness of the anode depends on the material employed, it is generally selected in the range of 10 nm to 1 μm, and preferably selected in the range of 10 to 200 nm.

### <<Cathode>>

As a cathode, a metal having a small work function (4 eV or less) (it is called as an electron injective metal), an alloy, a conductive compound and a mixture thereof are utilized as an electrode substance. Specific examples of the aforesaid electrode substance includes: sodium, sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, and a rare earth metal. Among them, with respect to an electron injection property and durability against oxidation, preferable are: a mixture of election injecting metal with a second metal which is stable metal having a work function larger than the electron injecting metal. Examples thereof are: a magnesium/silver mixture, a magnesium/aluminum mixture, a magnesium/indium mixture, an aluminum/aluminum oxide (Al₂O₃) mixture, a lithium/aluminum mixture and aluminum.

A cathode may be made by using these electrode substances with a method such as a vapor deposition method or a sputtering method to form a thin film. A sheet resistance of the cathode is preferably a few hundred Ω/sq or less. A layer thickness of the cathode is generally selected in the range of 10 nm to 5 μm, and preferably selected in the range of 50 to 200 nm.

In order to transmit emitted light, it is preferable that one of an anode and a cathode of an organic EL element is transparent or translucent for achieving an improved luminescence.

Further, after forming a layer of the aforesaid metal having a thickness of 1 to 20 nm on the cathode, it is possible to prepare a transparent or translucent cathode by providing with a conductive transparent material described in the description for the anode thereon. By applying this process, it is possible to produce an element in which both an anode and a cathode are transparent.

### <<Support Substrate>>

A support substrate which may be used for an organic EL element of the present invention is not specifically limited with respect to types such as glass and plastics. Hereafter, the support substrate may be also called as substrate body, substrate, substrate substance, or support. They may be transparent or opaque. However, a transparent support substrate is preferable when the emitting light is taken from the side of the support substrate. Support substrates preferably utilized includes such as glass, quartz and transparent resin film. A specifically preferable support substrate is a resin film capable of providing an organic EL element with a flexible property.

Examples of a resin film include: polyesters such as polyethylene terephthalate (PET) and polyethylene naphthalate (PEN), polyethylene, polypropylene, cellophane, cellulose esters and their derivatives such as cellulose diacetate, cellulose triacetate (TAC), cellulose acetate butyrate, cellulose acetate propionate (CAP), cellulose acetate phthalate, and cellulose nitrate, polyvinylidene chloride, polyvinyl alcohol, polyethylene vinyl alcohol, syndiotactic polystyrene, polycarbonate, norbornene resin, polymethyl pentene, polyether ketone, polyimide, polyether sulfone (PES), polyphenylene sulfide, polysulfones, polyether imide, polyether ketone imide, polyamide, fluororesin, Nylon, polymethyl methacrylate, acrylic resin, polyallylates and cycloolefin resins such as ARTON (trade name, made by JSR Co. Ltd.) and APEL (trade name, made by Mitsui Chemicals, Inc.).

On the surface of a resin film, it may be formed a film incorporating an inorganic or an organic compound or a hybrid film incorporating both compounds. Barrier films are preferred with a water vapor permeability of 0.01 g/(m²·24 h) or less (at 25±0.5° C., and 90±2% RH) determined based on JIS K 7129-1992. Further, high barrier films are preferred to have an oxygen permeability of 10⁻³ ml/(m²·24 h·atm) or less determined based on JIS K 7126-1987, and a water vapor permeability of 10⁻⁵ g/(m²·24 h) or less.

As materials that form a barrier film, employed may be those which retard penetration of moisture and oxygen, which deteriorate the element. For example, it is possible to employ silicon oxide, silicon dioxide, and silicon nitride. Further, in order to improve the brittleness of the aforesaid film, it is more preferable to achieve a laminated layer structure of inorganic layers and organic layers. The laminating order of the inorganic layer and the organic layer is not particularly limited, but it is preferable that both are alternatively laminated a plurality of times.

Barrier film forming methods are not particularly limited. Examples of an employable method include: a vacuum deposition method, a sputtering method, a reactive sputtering method, a molecular beam epitaxy method, a cluster ion beam method, an ion plating method, a plasma polymerization method, a plasma CVD method, a laser CVD method, a thermal CVD method, and a coating method. Of these, specifically preferred is a method employing an atmospheric pressure plasma polymerization method, described in JP-A No. 2004-68143.

Examples of an opaque support substrate include metal plates such aluminum or stainless steel films, opaque resin substrates, and ceramic substrates.

An external taking out quantum efficiency of light emitted by the organic EL element of the present invention is preferably 1% or more at a room temperature, more preferably it is 5% or more.

External taking out quantum efficiency (%)=(Number of photons emitted by the organic EL element to the exterior/Number of electrons fed to the organic EL element)×100.

Further, it may be used simultaneously a color hue improving filter such as a color filter, or it may be used simultaneously a color conversion filter which convert emitted light color from the organic EL element to multicolor by employing fluorescent materials.

### <<Sealing>>

As a sealing means employed for sealing an organic EL element of the present invention, listed may be, for example, a method in which a sealing member, electrodes, and a supporting substrate are subjected to adhesion via adhesives. The sealing member may be arranged to cover the display region of an organic EL element, and may be a concave plate or a flat plate. Neither transparency nor electrical insulation is limited.

Specifically listed are glass plates, polymer plate-films, metal plate-films. Specifically, it is possible to list, as glass plates, soda-lime glass, barium-strontium containing glass, lead glass, aluminosilicate glass, borosilicate glass, barium borosilicate glass, and quartz. Further, listed as polymer plates may be polycarbonate, acryl, polyethylene terephthalate, polyether sulfide, and polysulfone. As a metal plate, listed are those composed of at least one metal selected from the group consisting of stainless steel, iron, copper, aluminum magnesium, nickel, zinc, chromium, titanium, molybdenum, silicon, germanium, and tantalum, or alloys thereof.

In the present invention, since it is possible to achieve a thin organic EL element, it is preferable to employ a polymer film or a metal film. Further, it is preferable that the polymer film has an oxygen permeability of 1×10⁻³ ml/(m²·24 h·atm) or less determined by the method based on JIS K 7126-1987, and a water vapor permeability of 1×10⁻³ g/(m²·24 h) or less (at 25±0.5° C., and 90±2% RH) determined by the method based on JIS K 7129-1992.

Conversion of the sealing member into concave is carried out by employing a sand blast process or a chemical etching process.

In practice, as adhesives, listed may be photo-curing and heat-curing types having a reactive vinyl group of acrylic acid based oligomers and methacrylic acid, as well as moisture curing types such as 2-cyanoacrylates. Further listed may be thermal and chemical curing types (mixtures of two liquids) such as epoxy based ones. Still further listed may be hot-melt type polyamides, polyesters, and polyolefins. Yet further listed may be cationically curable type UV curable epoxy resin adhesives.

In addition, since an organic EL element is occasionally deteriorated via a thermal process, preferred are those which enable adhesion and curing between room temperature and 80° C. Further, desiccating agents may be dispersed into the aforesaid adhesives. Adhesives may be applied onto sealing portions via a commercial dispenser or printed on the same in the same manner as screen printing.

Further, it is appropriate that on the outside of the aforesaid electrode which interposes the organic layer and faces the support substrate, the aforesaid electrode and organic layer are covered, and in the form of contact with the support substrate, inorganic and organic material layers are formed as a sealing film. In this case, as materials that form the aforesaid film may be those which exhibit functions to retard penetration of moisture or oxygen which results in deterioration. For example, it is possible to employ silicon oxide, silicon dioxide, and silicon nitride.

Still further, in order to improve brittleness of the aforesaid film, it is preferable that a laminated layer structure is formed, which is composed of these inorganic layers and layers composed of organic materials. Methods to form these films are not particularly limited. It is possible to employ, for example, a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a thermal CVD method, and a coating method.

It is preferable to inject a gas phase and a liquid phase material of inert gases such as nitrogen or argon, and inactive liquids such as fluorinated hydrocarbon or silicone oil into the space between the space formed with the sealing member and the display region of the organic EL element. Further, it is possible to form vacuum in the space. Still further, it is possible to enclose hygroscopic compounds in the interior of the space.

Examples of a hygroscopic compound include: metal oxides (for example, sodium oxide, potassium oxide, calcium oxide, barium oxide, magnesium oxide, and aluminum oxide); sulfates (for example, sodium sulfate, calcium sulfate, magnesium sulfate, and cobalt sulfate); metal halides (for example, calcium chloride, magnesium chloride, cesium fluoride, tantalum fluoride, cerium bromide, magnesium bromide, barium iodide, and magnesium iodide); perchlorates (for example, barium perchlorate and magnesium perchlorate). In sulfates, metal halides, and perchlorates, suitably employed are anhydrides. For sulfate salts, metal halides and perchlorates, suitably used are anhydrous salts.

### <<Protective Film and Protective Plate>>

On the aforesaid sealing film which interposes the organic layer and faces the support substrate or on the outside of the aforesaid sealing film, a protective or a protective plate may be arranged to enhance the mechanical strength of the element. Specifically, when sealing is achieved via the aforesaid sealing film, the resulting mechanical strength is not always high enough, therefore it is preferable to arrange the protective film or the protective plate described above. Usable materials for these include glass plates, polymer plate-films, and metal plate-films which are similar to those employed for the aforesaid sealing. However, from the viewpoint of reducing weight and thickness, it is preferable to employ a polymer film.

### <<Improving Method of Light Extraction>>

It is generally known that an organic EL element emits light in the interior of the layer exhibiting the refractive index (being about 1.6 to 2.1) which is greater than that of air, whereby only about 15% to 20% of light generated in the light emitting layer is extracted. This is due to the fact that light incident to an interface (being an interface between a transparent substrate and air) at an angle of Θ which is at least critical angle is not extracted to the exterior of the element due to the resulting total reflection, or light is totally reflected between the transparent electrode or the light emitting layer and the transparent substrate, and light is guided via the transparent electrode or the light emitting layer, whereby light escapes in the direction of the element side surface.

Means to enhance the efficiency of the aforesaid light extraction include, for example: a method in which roughness is formed on the surface of a transparent substrate, whereby total reflection is minimized at the interface of the transparent substrate to air (U.S. Pat. No. 4,774,435), a method in which efficiency is enhanced in such a manner that a substrate results in light collection (JP-A No. 63-314795), a method in which a reflection surface is formed on the side of the element (JP-A No. 1-220394), a method in which a flat layer of a middle refractive index is introduced between the substrate and the light emitting body and an antireflection film is formed (JP-A No. 62-172691), a method in which a flat layer of a refractive index which is equal to or less than the substrate is introduced between the substrate and the light emitting body (JP-A No. 2001-202827), and a method in which a diffraction grating is formed between the substrate and any of the layers such as the transparent electrode layer or the light emitting layer (including between the substrate and the outside) (JP-A No. 11-283751).

In the present invention, it is possible to employ these methods by combining with the organic EL element of the present invention. Of these, it is possible to appropriately employ the method in which a flat layer of a refractive index which is equal to or less than the substrate is introduced between the substrate and the light emitting body and the method in which a diffraction grating is formed between any layers of a substrate, and a transparent electrode layer and a light emitting layer (including between the substrate and the outside space).

By combining these means, the present invention enables to produce an element which exhibits higher luminance or excellent durability.

When a low refractive index medium having a thickness, greater than the wavelength of light is formed between the transparent electrode and the transparent substrate, the extraction efficiency of light emitted from the transparent electrode to the exterior increases as the refractive index of the medium decreases.

As materials of the low refractive index layer, listed are, for example, aerogel, porous silica, magnesium fluoride, and fluorine based polymers. Since the refractive index of the transparent substrate is commonly about 1.5 to 1.7, the refractive index of the low refractive index layer is preferably approximately 1.5 or less. More preferably, it is 1.35 or less.

Further, thickness of the low refractive index medium is preferably at least two times of the wavelength in the medium. The reason is that, when the thickness of the low refractive index medium reaches nearly the wavelength of light so that electromagnetic waves escaped via evanescent enter into the substrate, effects of the low refractive index layer are lowered.

The method in which the interface which results in total reflection or a diffraction grating is introduced in any of the media is characterized in that light extraction efficiency is significantly enhanced. The above method works as follows. By utilizing properties of the diffraction grating capable of changing the light direction to the specific direction different from diffraction via so-called Bragg diffraction such as primary diffraction or secondary diffraction of the diffraction grating, of light emitted from the light entitling layer, light, which is not emitted to the exterior due to total reflection between layers, is diffracted via introduction of a diffraction grating between any layers or in a medium (in the transparent substrate and the transparent electrode) so that light is extracted to the exterior.

It is preferable that the introduced diffraction grating exhibits a two-dimensional periodic refractive index. The reason is as follows. Since light emitted in the light emitting layer is randomly generated to all directions, in a common one-dimensional diffraction grating exhibiting a periodic refractive index distribution only in a certain direction, light which travels to the specific direction is only diffracted, whereby light extraction efficiency is not sufficiently enhanced.

However, by changing the refractive index distribution to a two-dimensional one, light, which travels to all directions, is diffracted, whereby the light extraction efficiency is enhanced. A position to introduce a diffraction grating may be between any layers or in a medium (in a transparent substrate or a transparent electrode). However, a position near the organic light emitting layer, where light is generated, is preferable. In this case, the cycle of the diffraction grating is preferably from about ½ to 3 times of the wavelength of light in the medium. The preferable arrangement of the diffraction grating is such that the arrangement is two-dimensionally repeated in the form of a square lattice, a triangular lattice, or a honeycomb lattice.

### <<Light Collection Sheet>>

Via a process to arrange a structure such as a micro-lens array shape on the light extraction side of the organic EL element of the present invention or via combination with a so-called light collection sheet, light is collected in the specific direction such as the front direction with respect to the light emitting element surface, whereby it is possible to enhance luminance in the specific direction.

In an example of the micro-lens array, square pyramids to realize a side length of 30 μm and an apex angle of 90 degrees are two-dimensionally arranged on the light extraction side of the substrate. The side length is preferably 10 to 100 μm. When it is less than the lower limit, coloration occurs due to generation of diffraction effects, while when it exceeds the upper limit, the thickness increases undesirably.

It is possible to employ, as a light collection sheet, for example, one which is put into practical use in the LED backlight of liquid crystal display devices. It is possible to employ, as such a sheet, for example, the luminance enhancing film (BEF), produced by Sumitomo 3M Limited. As shapes of a prism sheet employed may be, for example, A shaped stripes of an apex angle of 90 degrees and a pitch of 50 μm formed on a base material, a shape in which the apex angle is rounded, a shape in which the pitch is randomly changed, and other shapes.

Further, in order to control the light radiation angle from the light emitting element, simultaneously employed may be a light diffusion plate-film. For example, it is possible to employ the diffusion film (LIGHT-UP), produced by Kimoto Co., Ltd.

### <<Applications>>

It is possible to employ the organic EL element of the present invention as display devices, displays, and various types of light emitting sources. Examples of a light emitting source include: lighting devices (home lighting and car interior lighting), clocks, backlights for liquid crystals, sign advertisements, signals, light sources of light memory media, light sources of electrophotographic copiers, light sources of light communication processors, and light sources of light sensors. The present invention is not limited to them. It is especially effectively employed as a backlight of a liquid crystal display device and a lighting source.

If needed, the organic EL element of the present, invention may undergo patterning via a metal mask or an ink-jet printing method during film formation. When the patterning is carried out, only an electrode may undergo patterning, an electrode and a light emitting layer may undergo patterning, or all element layers may undergo patterning. During preparation of the element, it is possible to employ conventional methods.

### <<Display Device>>

Hereafter, one example of a display device provided with an organic EL element of the present invention will be explained with reference to figures.

FIG. 4 is a schematic perspective drawing to show an example of a display device constituted of an organic EL element of the present invention. It displays image information by emission of an organic EL element. An example is a mobile phone. As illustrated in FIG. 4, a display 1 is constituted of a display section A having plural number of pixels and a control section B which performs image scanning of the display section A based on image information.

The control section B, which is electrically connected to the display section A, sends a scanning signal and an image data signal to plural number of pixels based on image information from the outside and pixels of each scanning line successively emit depending on the image data signal by a scanning signal to perform image scanning, whereby image information is displayed on the display section A.

FIG. 5 is a schematic drawing of the display section A illustrated in FIG. 4.

The display section A is provided with a wiring part, which contains plural scanning lines 5 and data lines 6, and plural pixels 3 on a substrate.

Primary members of the display section A will be explained in the following.

In FIG. 5, it is illustrated the case that light emitted by a pixel 3 is taken out along a white arrow (downward). Scanning lines 5 and plural data lines 6 in a wiring part each are composed of a conductive material, and the scanning lines 5 and the data lines 6 are perpendicular in a grid form and are connected to the pixels 3 at the right-angled crossing points (details are not shown in the drawing).

The pixel 3 receives an image data from the data line 6 when a scanning signal is applied from the scanning line 5 and emits according to the received image data.

A full-color display device is achieved by appropriately arranging pixels each having an emission color in a red region, in a green region, and in a blue region, being placed side by side on the same substrate.

### <<Lighting Device>>

One of the embodiments of a lighting device provided with an organic EL element of the present invention will be described.

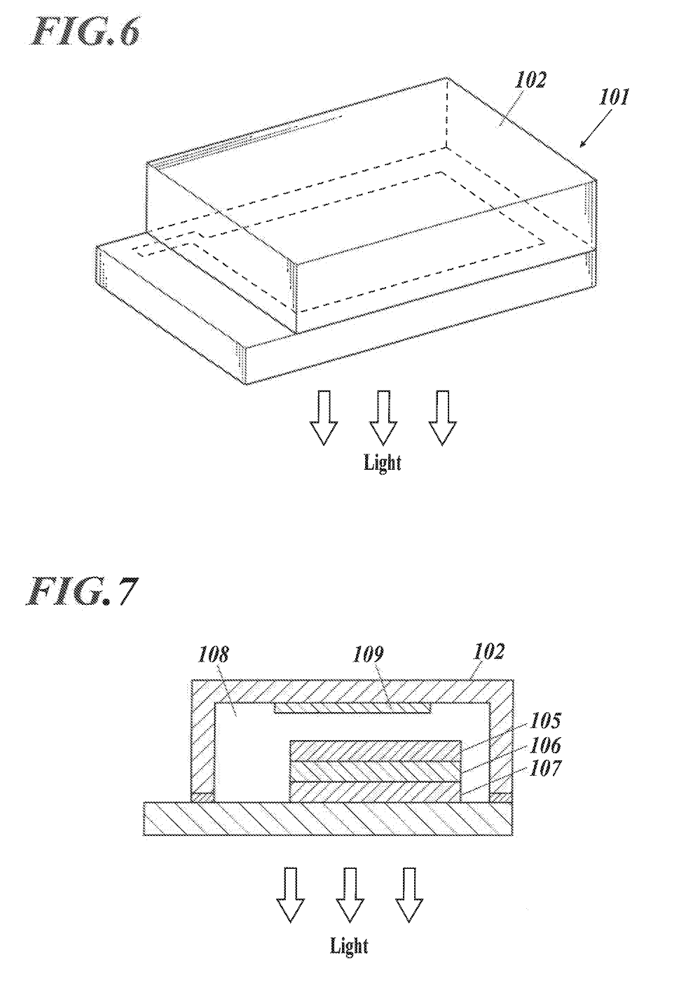

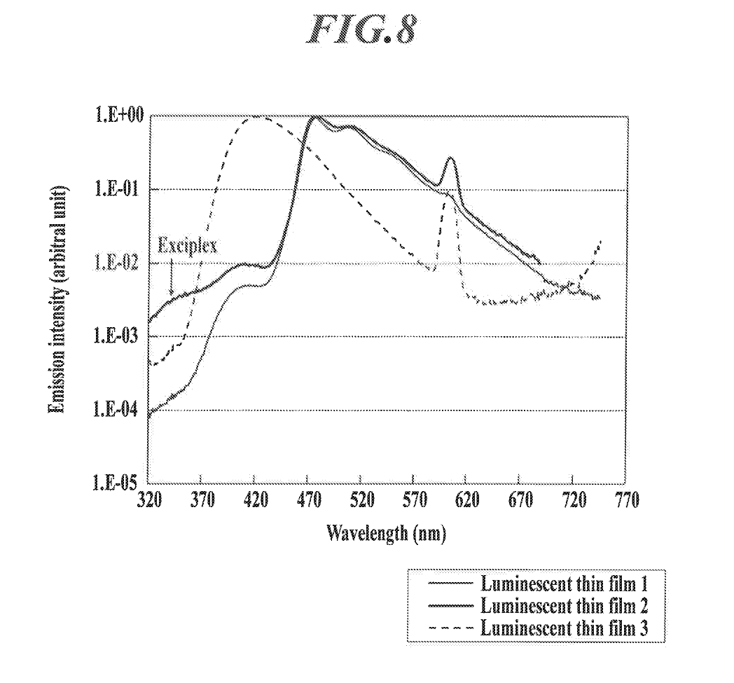

The non-light emitting surface of the organic EL element of the present invention was covered with a glass case, and a 300 μm thick glass substrate was employed as a sealing substrate. An epoxy based light curable type adhesive (LUXTRACK LC0629B produced by Toagosei Co., Ltd.) was employed in the periphery as a sealing material. The resulting one was superimposed on the aforesaid cathode to be brought into close contact with the aforesaid transparent support substrate, and curing and sealing were carried out via exposure of UV radiation onto the glass substrate side, whereby the lighting device shown in FIG. 6 and FIG. 7 was formed.

FIG. 6 is a schematic view of a lighting device. An organic EL element 101 of the present invention is covered with a glass cover 102 (incidentally, sealing by the glass cover was carried out in a globe box under nitrogen ambience (under air ambience of high purity nitrogen gas at a purity of at least 99.999%) so that the organic EL Element 101 was not brought into contact with atmosphere.

FIG. 7 is a cross-sectional view of a lighting device. In FIG. 7, 105 represents a cathode, 106 represents an organic EL layer (light emitting unit), and 107 represents a glass substrate fitted with a transparent electrode. Further, the interior of glass cover 102 is filled with nitrogen gas 108 and a water catching agent 109 is provided.

### EXAMPLES

Hereafter, the present invention will be described specifically by referring to Examples, however, the present invention is not limited to them. In Examples, the term “parts” or “%” is used. Unless particularly mentioned, they respectively represent “mass parts” or “mass %”.

### Example 1

Various compounds used in the present examples are the following compounds in addition to the aforesaid compounds.

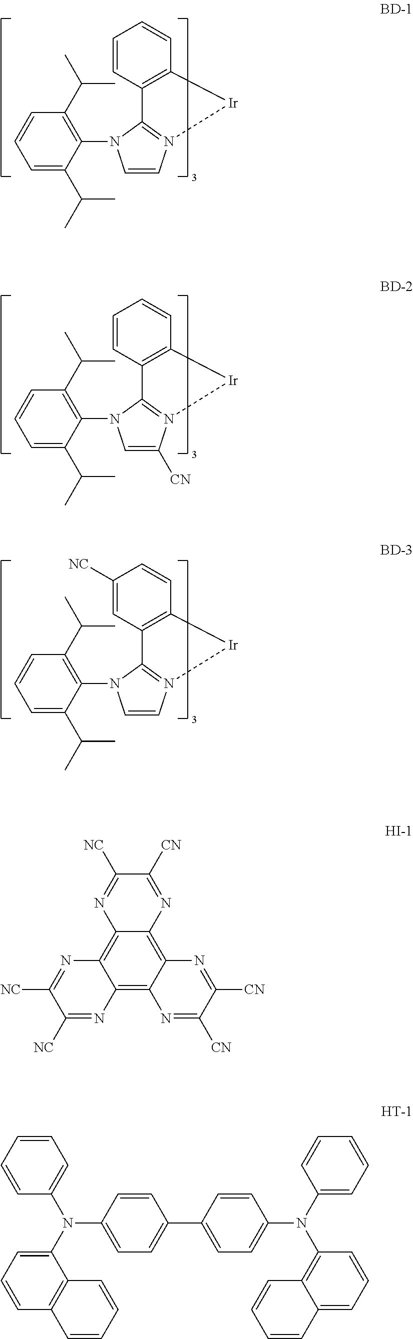

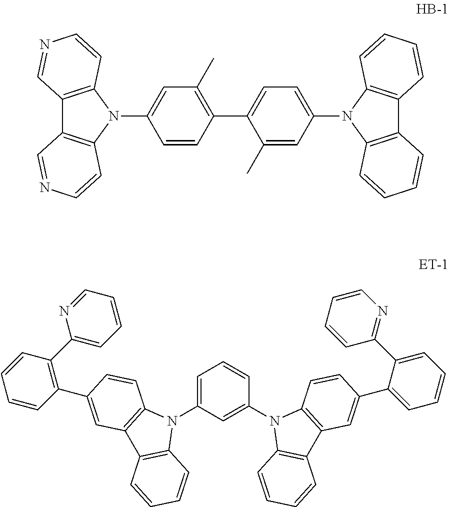 [SMILES: Cc1cc(-n2c3ccccc3c3ccccc32)ccc1-c1ccc(-n2c3ccncc3c3cnccc32)cc1C ; c1ccc(-c2ccccc2-c2ccc3c(c2)c2ccccc2n3-c2cccc(-n3c4ccccc4c4cc(-c5ccccc5-c5ccccn5)ccc43)c2)nc1]

### <<Preparation of Luminescent Thin Film for Evaluation>>

A quartz glass substrate of 50 mm×50 mm having a thickness of 0.7 mm was ultrasonically washed with isopropyl alcohol, followed by drying with desiccated nitrogen gas, and it was subjected to UV ozone washing for 5 minutes. The resulting transparent substrate was fixed to a substrate holder of a commercial vacuum deposition apparatus. “A host compound” and “a dopant” indicated in Table 1 were loaded in each heating boat for vapor deposition in the vacuum deposition apparatus with an optimum amount for producing each element. As a heating boat for vapor deposition, a resistance heating boat made of molybdenum or tungsten was used.

After reducing the pressure of the inside of the vacuum deposition apparatus to 1×10⁻⁴ Pa, the host compound and the dopant were co-deposited at a deposition rate of 0.1 nm/second to achieve the volume ratio as described in Table 1 by using the host compound and the dopant indicated in Table 1. Thus, luminescent thin films for evaluation 1, 2, and 3 having a thickness of 30 nm were produced.

The above-described luminescent thin films for evaluation 1, 2, and 3 were covered with a glass case under the atmosphere of high purity nitrogen gas (purity of 99.999% or more), and a 300 μm thick glass substrate was employed as a sealing substrate. An epoxy based light curable type adhesive (LUXTRACK LC0629B produced by Toagosei Co., Ltd.) was employed in the periphery as a sealing material. The resulting one was brought into close contact with the aforesaid quartz substrate, and curing was carried out via exposure of UV radiation onto the glass substrate side, whereby sealing was performed.

### <<Measurement of Emission Spectrum of Luminescent Thin Film>>

The emission spectrum was measured using a spectrofluorometer (F-7000, made by Hitachi Co., Ltd.) at room temperature (300 K). The emission spectra of the luminescent thin films 1, 2 and 3 were indicated in FIG. 8. The horizontal axis represents wavelength (nm), and the vertical axis represents emission intensity (arbitral unit). The luminescent thin films 1 and 2 both exhibited normal temperature phosphorescence emission at about 470 nm due to the metal oxide and fluorescence emission at about 400 nm due to the host compound. The luminescent thin film 2 of the present invention exhibited a new emission peak at about 360 nm, while the comparative luminescent thin film 1 did not give this emission peak. The new emission peak around 360 nm is considered to be a light emission due to the exciplex formation of the dopant and the host compound.

### <<Evaluation of Emission Lifetime>>

Luminance retention rate in UV irradiation test using an HgXe light source was determined according to the following method.

A mercury-Xenon lamp UV irradiation apparatus LC8 (made by Hamamatsu Photonics, Co. Ltd.) was used in the UV irradiation test using an HgXe light source. A9616-05 was attached as a UV cut filter. The emission surface of the irradiation fiber and the glass cover surface of the sample (thin film for evaluation) were placed horizontally, and irradiation was done until the number of luminescent photons was reduced to be half with a distance of 1 cm. The measurement was carried out under the condition of room temperature (300 K).

The time (half-decay time) required for achieving the number of luminescent photons to be reduced to half was measured for each luminescent thin films for evaluation. A relative value (LT 50 ratio) was obtained with the value of the luminescent thin film 1 at room temperature (300 K) being set to be 1.0.

The measurement of luminance (the number of emission photons) was carried out from an angle tilted 45 degrees from the axis of the irradiation fiber with Spectroradiometer CS-1000 (manufactured by Konica Minolta. Inc.).

The measurement results of the emission lifetime were indicated in Table 2. It can be recognized that the emission lifetime of the luminescent thin film 2 of the present invention is greatly improved with respect to the comparative luminescent thin film 1. In the luminescent thin film 2 of the present invention, it is considered that the durability was improved by forming an exciplex of a dopant and a host compound.

TABLE 1

| | Dopant | | Host compound | | |
|---|---|---|---|---|---|
| Luminescent | | Volume | | Volume | |
| thin film No. | No. | (%) | No. | (%) | Remarks |
| 1 | BD-1 | 15 | H-10 | 85 | Comparative example |
| 2 | CD-1 | 15 | H-10 | 85 | Present invention |

| | | | | |
|---|---|---|---|---|
| 3 | — | H-10 | 100 | Comparative example |

TABLE 2

| Luminescent | LT 50 ratio | |
|---|---|---|
| thin film No. | (relative value) | Remarks |
| 1 | 1.0 | Comparative example |
| 2 | 2.6 | Present invention |

### <<Preparation of Lighting Device>>

An anode was prepared by making patterning to a glass substrate of 50 mm×50 mm having a thickness of 0.7 mm on which ITO (indium tin oxide) was formed beforehand with a thickness of 150 nm. Thereafter, the above transparent substrate provided with the ITO transparent electrode was subjected to ultrasonic washing with isopropyl alcohol, followed by drying with desiccated nitrogen gas, and was subjected to UV ozone washing for 5 minutes. The resulting transparent substrate was fixed to a substrate holder of a commercial vacuum deposition apparatus.

The constituting materials for each layer were loaded in each resistance heating boat for vapor deposition in the vacuum deposition apparatus with an optimum amount for producing each element. As a resistance heating boat for vapor deposition, it was used a resistance heating boat made of molybdenum or tungsten.

After reducing the pressure of a vacuum tank to 1×10⁻⁴ Pa, the resistance heating boat containing HI-1 was heated via application of electric current and vapor deposition was made onto the ITO transparent electrode at a deposition rate of 0.1 nm/second, whereby it was produced a hole injection layer having a thickness of 10 nm.

Subsequently, HT-1 was vapor deposited onto the hole injection layer at a deposition rate of 0.1 nm/second, whereby it was produced a hole transport layer having a thickness of 30 nm.

Subsequently, the resistance heating boats each respectively containing “a host compound” and “a dopant” as indicated in Table 3 to Table 5 were heated via application of electric current. Co-deposition was made onto the hole transport layer so as to obtain 85 volume % of the host compound and 15 volume % of the dopant at a respective deposition rate of 0.085 nm/second and 0.015 nm/second, whereby it was produced a light emitting layer having a thickness of 30 nm. When two kinds of host compounds were used, its volume ration was indicated in parentheses of the column of the host compound.

Subsequently, HB-1 was vapor deposited at a deposition rate of 0.1 nm/second, whereby it was produced a first electron transport layer having a thickness of 5 nm. Further, ET-1 was vapor deposited thereon at a deposition rate of 0.1 nm/second, whereby it was produced a second electron transport layer having a thickness of 45 nm. Subsequently, 0.5 nm thick lithium fluoride was vapor deposited, and then, 100 nm thick aluminum was vapor deposited to form a cathode, whereby an organic EL element for evaluation was prepared.

### <<Measurement of Emission Spectrum>>

Luminescent thin films were respectively prepared in the same manner as preparation of the luminescent thin films 1 to 3 produced by using a combination of a host compound and a dopant as indicated in Tables 3, 4 and 5. Emission spectrum of each luminescent thin film was measured. When the luminescent thin film according to the present invention was measured, a new emission peak was observed in the region different from the region of the thin film in which the host compound or the dopant was prepared alone. It was confirmed that an exciplex was formed. Among the luminescent thin films of the present invention, in 1-15, 1-16, 1-17, 1-18, 2-11, and 2-12, two exciplex emissions were observed: one is an exciplex emission formed with a phosphorescent metal complex and the one host compound, and the other is an exciplex emission formed with the other host compounds. On the other hand, in the comparative luminescent thin film, it was confirmed that no new peak was observed.

In Tables, 3, 4 and 5, with respect to the evaluation of the luminescent thin film used for each lighting device, when production of exciplex was observed, it was indicated by “o”, and when it was not observed, it was indicated by “x”.

The presence or absence of thermally activated delayed fluorescence of the host compound was judged by transient PL measurement. It was indicated as “o” when it was observed, and it was indicated as “x” when it was not observed.

After preparation of the organic EL element, the non-light emitting surface of the prepared organic EL element 101 was covered with a glass cover under the atmosphere of high purity nitrogen gas of 99.999% or more. A glass substrate having a thickness of 300 μm was used as a sealing substrate. As a sealing material, an epoxy-based light curable adhesive (LUXTRACK LC0629B produced by Toagosei Co., Ltd,) was applied to the periphery of the glass cover. The resulting one was superimposed on the cathode side to be brought into close contact with the transparent substrate. Curing and sealing were carried out via exposure of UV radiation onto the glass substrate side, whereby the lighting device for evaluation having the constitution illustrated in FIG. 6 and FIG. 7 was formed.

### <<Evaluation of Continuous Driving Stability (Half-Decay Lifetime)>>

Luminance of each lighting device for evaluation was measured using Spectroradiometer CS-2000. The time (LT50) required for reducing the luminance to the half was measured. It was determined as a half-decay time. The driving condition was set to be an electric current of 15 mA/cm².

BD-1 was made to be a comparative sample in Table 3, BD-2 was made to be a comparative sample in Table 4, and BD-3 was made to be a comparative sample in Table 5. A relative value (half-decay lifetime: relative value) was determined when the half-decay lifetimes of the lighting devices 1-1, 1-2 and 1-3 each were set to be 1.0.

### <<Evaluation of Expression (I)>>

An energy level of a lowest unoccupied molecular orbital of the phosphorescent metal complex was made to be LUMO(D), an energy level of a highest occupied molecular orbital of the host compound was made to be HOMO(H), and S₁ (min) was made to be a lower energy level obtained by comparing an energy level of an excited singlet state of the phosphorescent metal complex and an energy level of an excited singlet state of the host compound. It was examined whether Expression (I) was satisfied or not with a molecular orbital calculation software Gaussian 98 (made by Gaussian Co., Ltd.). When Expression (I) was satisfied, it was indicated as “−”, and when Expression (I) was not satisfied and the calculation result was a positive value, it was indicated as “+”.

[LUMO(D)−HOMO(H)]−[S₁ (min)]<0 (eV) Expression (I):

TABLE 3

| | | | | | | | Thermally | | |
|---|---|---|---|---|---|---|---|---|---|
| | | | | Half-decay | | | activated | | |
| Lighting | | | | lifetime | Exciplex formation | Exciplex | delayed | [LUMO (D)- | |
| device | Luminescent | | Host | (relative | between Dopant and | formation between | fluorescence | HOMO (H)]- | |
| No. | thin film No. | Dopant | compound | value) | Host compound | Host compounds | of Host | [S₁ (min)] | Remarks |
| 1-1 | 1-1 | BD-1 | H-3 | 1.0 | X | X | X | + | Comparative |
| | | | | | | | | | example |
| 1-2 | 1-2 | BD-1 | H-4 | 1.2 | X | X | X | + | Comparative |
| | | | | | | | | | example |
| 1-3 | 1-3 | BD-1 | H-7 | 0.7 | X | X | X | + | Comparative |
| | | | | | | | | | example |
| 1-4 | 1-4 | BD-1 | H-18 | 0.5 | X | X | ◯ | + | Comparative |
| | | | | | | | | | example |
| 1-5 | 1-5 | CD-1 | H-3 | 2.0 | ◯ | X | X | − | Present |
| | | | | | | | | | invention |
| 1-6 | 1-6 | CD-1 | H-4 | 2.5 | ◯ | X | X | − | Present |
| | | | | | | | | | invention |
| 1-7 | 1-7 | CD-1 | H-7 | 1.8 | ◯ | X | X | − | Present |
| | | | | | | | | | invention |
| 1-8 | 1-8 | CD-1 | H-18 | 1.1 | ◯ | X | ◯ | − | Present |
| | | | | | | | | | invention |
| 1-9 | 1-9 | CD-2 | H-4 | 1.4 | ◯ | X | X | − | Present |
| | | | | | | | | | invention |
| 1-10 | 1-10 | CD-2 | H-7 | 1.7 | ◯ | X | X | − | Present |
| | | | | | | | | | invention |
| 1-11 | 1-11 | CD-7 | H-4 | 1.8 | ◯ | X | X | − | Present |
| | | | | | | | | | invention |
| 1-12 | 1-12 | CD-7 | H-7 | 1.5 | ◯ | X | X | − | Present |
| | | | | | | | | | invention |
| 1-13 | 1-13 | BD-1 | H-3 + H-13 | 1.3 | X | ◯ | X | + | Comparative |
| | | | (1:1) | | | | | | example |
| 1-14 | 1-14 | BD-1 | H-4 + H-13 | 1.5 | X | ◯ | X | + | Comparative |
| | | | (1:1) | | | | | | example |
| 1-15 | 1-15 | CD-1 | H-3 + H-13 | 3.1 | ◯ | ◯ | X | − | Present |
| | | | (1:1) | | | | | | invention |
| 1-16 | 1-16 | CD-1 | H-4 + H-13 | 3.6 | ◯ | ◯ | X | − | Present |
| | | | (1:1) | | | | | | invention |
| 1-17 | 1-17 | CD-7 | H-3 + H-13 | 2.5 | ◯ | ◯ | X | − | Present |
| | | | (1:1) | | | | | | invention |
| 1-18 | 1-18 | CD-7 | H-4 + H-13 | 2.5 | ◯ | ◯ | X | − | Present |
| | | | (1:1) | | | | | | invention |

TABLE 4

| | | | | | | | Thermally | | |
|---|---|---|---|---|---|---|---|---|---|
| | | | | Half-decay | | | activated | | |
| Lighting | | | | lifetime | Exciplex formation | Exciplex | delayed | [LUMO (D)- | |
| device | Luminescent | | Host | (relative | between Dopant and | formation between | fluorescence | HOMO (H)]- | |
| No. | thin film No. | Dopant | compound | value) | Host compound | Host compounds | of Host | [S₁ (min)] | Remarks |
| 2-1 | 2-1 | BD-2 | H-1 | 1.0 | X | X | X | + | Comparative |
| | | | | | | | | | example |
| 2-2 | 2-2 | BD-2 | H-2 | 0.9 | X | X | X | + | Comparative |
| | | | | | | | | | example |
| 2-3 | 2-3 | BD-2 | H-5 | 1.2 | X | X | X | + | Comparative |
| | | | | | | | | | example |
| 2-4 | 2-4 | CD-3 | H-1 | 1.6 | ◯ | X | X | − | Present |
| | | | | | | | | | invention |
| 2-5 | 2-5 | CD-3 | H-2 | 1.5 | ◯ | X | X | − | Present |
| | | | | | | | | | invention |
| 2-6 | 2-6 | CD-3 | H-5 | 1.8 | ◯ | X | X | − | Present |
| | | | | | | | | | invention |
| 2-7 | 2-7 | CD-4 | H-1 | 1.5 | ◯ | X | X | − | Present |
| | | | | | | | | | invention |
| 2-8 | 2-8 | CD-4 | H-2 | 1.6 | ◯ | X | X | − | Present |
| | | | | | | | | | invention |
| 2-9 | 2-9 | CD-4 | H-5 | 2.1 | ◯ | X | X | − | Present |
| | | | | | | | | | invention |
| 2-10 | 2-10 | BD-2 | H-3 + H-11 | 1.3 | X | ◯ | X | + | Comparative |
| | | | (1:1) | | | | | | example |
| 2-11 | 2-11 | CD-3 | H-3 + H-11 | 2.1 | ◯ | ◯ | X | − | Present |
| | | | (1:1) | | | | | | invention |
| 2-12 | 2-12 | CD-4 | H-3 + H-11 | 2.6 | ◯ | ◯ | X | − | Present |
| | | | (1:1) | | | | | | invention |

TABLE 5

| | | | | Half-decay | | Exciplex | Thermally | | |
|---|---|---|---|---|---|---|---|---|---|
| Lighting | | | | lifetime | Exciplex formation | formation | activated delayed | [LUMO (D)- | |
| device | Luminescent | | Host | (relative | between Dopant and | between | fluorescence | HOMO (H)]- | |
| No. | thin film No. | Dopant | compound | value) | Host compound | Host compounds | of Host | [S₁ (min)] | Remarks |
| 3-1 | 3-1 | BD-3 | H-4 | 1.0 | X | X | X | + | Comparative |
| | | | | | | | | | example |
| 3-2 | 3-2 | BD-3 | H-6 | 0.8 | X | X | X | + | Comparative |
| | | | | | | | | | example |
| 3-3 | 3-3 | BD-3 | H-8 | 0.7 | X | X | X | + | Comparative |
| | | | | | | | | | example |
| 3-4 | 3-4 | BD-3 | H-9 | 0.9 | X | X | X | + | Comparative |
| | | | | | | | | | example |
| 3-5 | 3-5 | BD-3 | H-10 | 0.7 | X | X | X | + | Comparative |
| | | | | | | | | | example |
| 3-6 | 3-6 | CD-5 | H-4 | 1.3 | ◯ | X | X | − | Present |
| | | | | | | | | | invention |
| 3-7 | 3-7 | CD-5 | H-6 | 1.2 | ◯ | X | X | − | Present |
| | | | | | | | | | invention |
| 3-8 | 3-8 | CD-5 | H-8 | 1.3 | ◯ | X | X | − | Present |
| | | | | | | | | | invention |
| 3-9 | 3-9 | CD-5 | H-9 | 1.5 | ◯ | X | X | − | Present |
| | | | | | | | | | invention |
| 3-10 | 3-10 | CD-5 | H-10 | 1.2 | ◯ | X | X | − | Present |
| | | | | | | | | | invention |
| 3-11 | 3-11 | CD-6 | H-4 | 1.2 | ◯ | X | X | − | Present |
| | | | | | | | | | invention |
| 3-12 | 3-12 | CD-8 | H-4 | 1.5 | ◯ | X | X | − | Present |
| | | | | | | | | | invention |
| 3-13 | 3-13 | CD-9 | H-4 | 1.7 | ◯ | X | X | − | Present |
| | | | | | | | | | invention |
| 3-14 | 3-14 | CD-10 | H-4 | 2.0 | ◯ | X | X | − | Present |
| | | | | | | | | | invention |

As indicated in Table 3, it was confirmed that the lighting devices 1-5 to 1-12 for evaluation, which used a combination of a dopant and a host compound that satisfied the requirement of the present invention and formed an exciplex, exhibited excellent continuous driving stability compared with a comparative example. Further, the lighting devices 1-15 to 1-18 for evaluation were prepared by employing a combination of a dopant and two kinds of host compounds. Wherein an exciplex was formed with a dopant and one kind host compound, and another exciplex was formed with a plurality of the other kind of host compounds. It was confirmed that they exhibited more excellent continuous driving stability. The same performance improvement can be confirmed by the results in Tables 4 and 5.

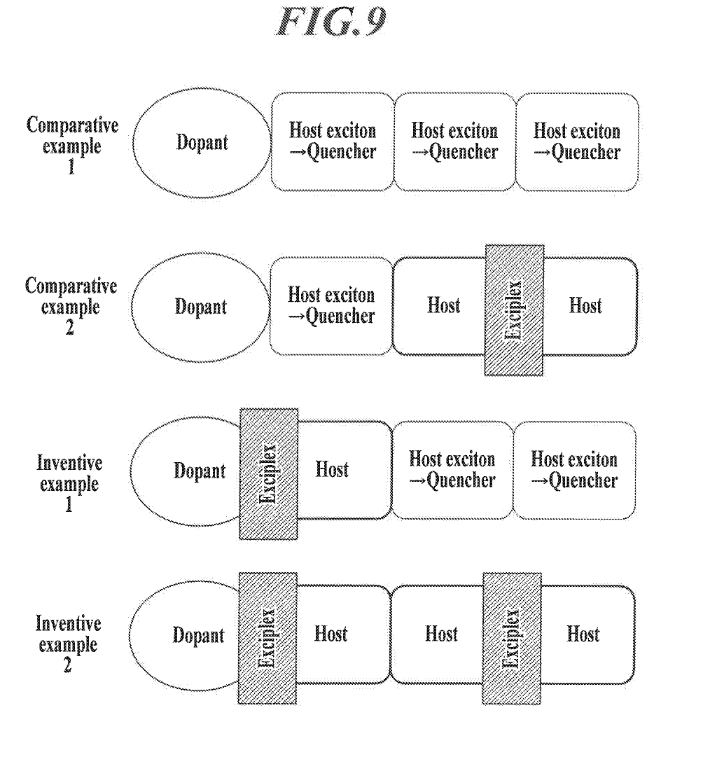

Based on the results described above, the effects of the present invention were summarized in FIG. 9. In a comparative example 1 in FIG. 9, there is high probability that all of the host compounds become an exciton to result in having the least stability. In a comparative example 2, since the host compound away from the dopant is less likely to become an exciton, it is better than the comparative example 1, but the host compound in the vicinity of the dopant may become an exciton, which is inferior to the present invention 1. In the present invention 2, it is considered that the stability is the highest since exciton formation in the host compound located in the vicinity of the dopant and located remotely may be suppressed.

### INDUSTRIAL APPLICABILITY

The luminescent thin film of the present invention has a high luminous efficiency and long luminescent lifetime. It is possible to provide an organic EL element having improved continuous driving stability by using this luminescent thin film. The organic EL element may be used for a display device, a display, and a variety of light emitting sources.

### DESCRIPTION OF SYMBOLS

### 1: Display

### 3: Pixel

5: Scanning line
6: Data line
A: Display section
B: Control section
101: Organic EL element
102: Glass cover

### 105: Cathode

106: Organic EL layer
107: Glass substrate having a transparent electrode

### 108: Nitrogen gas

109: Water catching agent

1. A luminescent thin film comprising: a phosphorescent metal complex; and a host compound that forms an exciplex with the phosphorescent metal complex.

2. The luminescent thin film described in claim 1,
wherein the phosphorescent metal complex has a structure represented by Formula (1), and emits light at room temperature, 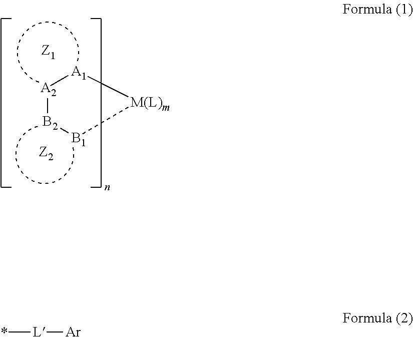
in Formula (1), M represents Ir or Pt; A₁, A₂, B₁, and B₂ each represent a carbon atom or a nitrogen atom; a ring Z₁ represents a 6-membered aromatic hydrocarbon ring, or a 5- or 6-membered aromatic heterocycle formed with A₁ and A₂, a ring Z₂ represents a 5- or 6-membered aromatic heterocycle formed with B₁ and B₂, one of a bond between A₁ and M and a bond between B₁ and M is a coordination bond, and the other is a covalent bond, the ring Z₁ and the ring Z₂ each respectively may have a substituent, and at least one of the ring Z₁ and the ring Z₂ have a substituent having a structure represented by Formula (2), the substituent on the ring Z₁ and the substituent on the ring Z₂ may be bonded together to form a condensed ring structure, ligands represented by the ring Z₁ and the ring Z₂ may be bonded together; L represents a monoanionic bidentate ligand coordinated to M, and L may have a substituent; m represents an integer of 0 to 2, n represents an integer of 1 to 4, when M represents Ir, (m+n) represents 3, and when M represents Pt, (m+n) represents 2, when m or n is an integer of 2 or more, the ligands represented by the ring Z₁ and the ring Z₂, and L each may be the same or different, and the ligand represented by the ring Z₁ and the ring Z₂ may be bonded to L;
in Formula (2), an asterisk mark (*) represents a linking site with the ring Z₁ or the ring Z₂ in Formula (1); L′ represents a single bond or a linking group; and Ar represents a substituent having an electron accepting property.

3. The luminescent thin film described in claim 1, comprising at least two kinds of host compounds,
wherein at least one kind of host compound is capable of forming an exciplex with the phosphorescent metal complex, and a plurality of the other kind of host compounds are capable of forming an exciplex with each other.

4. The luminescent thin film described in claim 1,
wherein the host compound that forms the exciplex with the phosphorescent metal complex is a compound capable of emitting thermally activated delayed fluorescence.

5. The luminescent thin film described in claim 1,
satisfying the following Expression (1):
[LUMO(D)−HOMO(H)]−[S₁ (min)]<0 (eV)
wherein LUMO(D) represents an energy level of a lowest unoccupied molecular orbital of the phosphorescent metal complex, HOMO(H) represents an energy level of a highest occupied molecular orbital of the host compound that forms the exciplex with the phosphorescent metal complex, and S₁ (min) represents a lower energy level obtained by comparing an energy level of an excited singlet state of the phosphorescent metal complex and an energy level of an excited singlet state of the host compound.

6. An organic electroluminescent element comprising at least a light emitting layer between an anode and a cathode,
wherein the light emitting layer contains the luminescent thin film described in claim 1.
